(19) United States
(12) Patent Application Publication
(10) Pub. No.: US 2012/0301732 A1
(43) Pub. Date: Nov. 29, 2012

(54) AL ALLOY FILM FOR USE IN DISPLAY DEVICE

(75) Inventors: Hiroyuki Okuno, Kobe-shi (JP); Toshihiro Kugimiya, Kobe-shi (JP); Hiroshi Goto, Kobe-shi (JP)

(73) Assignee: KABUSHIKI KAISHA KOBE SEIKO SHO (Kobe Steel, Ltd.), Kobe-shi, Hyogo (JP)

(21) Appl. No.: 13/576,053

(22) PCT Filed: Feb. 16, 2011
(86) PCT No.: PCT/JP2011/053300

§ 371 Date: Jul. 30, 2012

(30) Foreign Application Priority Data
Feb. 16, 2010 (JP) 2010-031310

(51) Int. Cl. C22C 21/00; B32B 15/04; C23C 14/14

(52) U.S. Cl. 428/457; 204/298.13; 148/415; 148/416

(57) ABSTRACT

Disclosed is an Al alloy film for use in a display device, which does not undergo the formation of hillocks even when exposed to high temperatures of about 450° C. to 600° C., and has excellent high-temperature heat resistance, low electrical resistance (wiring resistance) and excellent corrosion resistance under alkaline environments. Specifically disclosed is an Al alloy film for use in a display device, which comprises at least one element selected from a group X consisting of Ta, Nb, Re, Zr, W, Mo, V, Hf and Ti and at least one rare earth element, and which meets the following requirement (1) when heated at 450° C. to 600° C. (1) Precipitates each having an equivalent circle diameter of 20 nm or more are present at a density of 500,000 particles/mm² or more in a first precipitation product containing at least one element selected from Al and the elements included in the group X and at least one rare earth element.

### TECHNICAL FIELD

The present invention relates to an Al alloy film for use in a display device, such as a liquid crystal display, the Al alloy film being useful as an electrode and a wiring material, a display device including the Al alloy film, and a sputtering target used for the formation of the Al alloy film.

### BACKGROUND ART

Al alloy films for use in display devices are mainly used as electrodes and wiring materials. Examples of the electrodes and wiring materials include gate, source, and drain electrodes for a thin film transistor and a wiring material in a liquid crystal display (LDC); gate, source, and drain electrodes for a thin film transistor and a wiring material in an organic EL (OELD); cathode and gate electrodes and a wiring material in a field emission display (FED); an anode electrode and a wiring material in a vacuum fluorescent display (VFD); an address electrode and a wiring material in a plasma display (PDP); and a back electrode in an inorganic EL.

Hereinafter, while a liquid crystal display is representatively described as a liquid crystal display device, the present invention is not limited thereto.

Nowadays, large-sized liquid crystal displays having a size of more than 100 inches are commercialized and widely used as main display devices because of improvement in low power consumption technology. There are liquid crystal displays having different operating principles. Among them, active-matrix liquid crystal displays including thin film transistors (hereinafter, referred to as “TFTs”) used for the switching of pixels are dominant because they have high-precision image qualities and can support high-speed moving images. In liquid crystal displays required to have lower power consumption and higher switching speeds of pixels, TFTs including semiconductor layers composed of polycrystalline silicon and continuous grain silicon are used.

For example, active-matrix liquid crystal displays include TFT substrates including TFTs serving as switching elements, pixel electrodes formed of conductive oxide films, and wiring, such as scan lines and signal lines. Scan lines and signal lines are electrically connected to pixel electrodes. Wiring materials constituting scan lines and signal lines are formed of Al-based alloy thin films.

The structure of a core portion of a TFT substrate including a semiconductor layer composed of hydrogenated amorphous silicon will be described below with reference to FIG. 5.

As illustrated in FIG. 5, a scan line 25 is arranged on a glass substrate 1a. Part of the scan line 25 functions as a gate electrode 26 that controls the on/off state of a TFT. The gate electrode 26 is electrically insulated with a gate insulating film 27 (e.g., silicon nitride film). A semiconductor silicon layer 30 is arranged on the gate insulating film 27. Furthermore, a passivation film 31 (e.g., silicon nitride film) and so forth are arranged. The semiconductor silicon layer 30 is bonded to a source electrode 28 and a drain electrode 29 with a low-resistance silicon layer 32 and is electrically conductive.

The drain electrode 29 has a structure (called a “direct contact (DC)”) in which the drain electrode is in direct contact with a transparent electrode 5 composed of indium tin oxide (ITO). As an electrode wiring material used for the direct contact, Al alloys described in PTLs 1 to 5 are exemplified because Al has low electrical resistivity and excellent micro-machinability. These Al alloys are each directly connected to a transparent conductive oxide film constituting a transparent electrode or a semiconductor silicon layer without using a barrier metal layer composed of a refractory metal, such as Mo, Cr, Ti, and W.

These wiring films and electrodes 25 to 32 are covered with an insulating passivation film 33 composed of, for example, silicon nitride and supply the drain electrode 29 with electricity.

To ensure stable operating characteristics of the TFT illustrated in FIG. 5, in particular, it is necessary to increase the mobility of carriers (electrons and holes) in the semiconductor silicon layer 30. Thus, a production process of a liquid crystal display or the like includes a heat-treatment step of heat-treating a TFT, thereby resulting in microcrystallization or polycrystallization of the whole or part of the semiconductor silicon layer 30 having an amorphous structure. This increases the carrier mobility, improving the response speed of the TFT.

In the production process of the TFT, for example, the deposition of the insulating passivation film 33 is performed at a relatively low temperature of about 250° C. to about 350° C. To improve the stability of a TFT substrate (a liquid crystal display-driving portion in which TFTs are arranged in an array), high-temperature heat treatment at about 450° C. or higher is performed in some cases. In the actual production of a TFT, a TFT substrate, and a liquid crystal display, such low- or high-temperature heat treatment is performed two or more times, in some cases.

However, in the case where the heat-treatment temperature in a production process is a high temperature, such as about 450° C. or higher, and where such high-temperature heat treatment is performed for extended periods of time, the heat treatment causes delamination of the thin layers illustrated in FIG. 5 and atomic interdiffusion between thin layers in contact with each other, thereby degrading the thin layers. Hitherto, heat treatment has been performed only at a temperature of at most 300° C. or lower. If anything, the fact is that research and development on wiring materials used for TFTs and structures of display devices has been intensively conducted even if the heat-treatment temperature is minimized. This is because the entire production process of a TFT is thought to be ideally performed at room temperature from the technical point of view.

For example, in PTLs 1 to 5 described above, heat treatment is performed at about 200° C. to about 350° C. in order to reduce the contact resistance between an Al alloy wiring film and a transparent conductive film. Heat resistance as the overall TFT structure (in particular, heat resistance during heating at high temperatures) has not been considered. In an example of PTL 1, results when an silicon nitride insulating film is formed at 300° C. to 350° C. and when a gate wiring film is formed at 250° C. are described, whereas results when heat treatment is performed at a higher temperature are not described. PTL 2 aims to provide an Al alloy material for TFT wiring, the Al alloy material being particularly useful for heat treatment at low temperatures, and states that in an example, heat treatment at a low temperature of 200° C. is effective. Similarly, PTL 3 describes evaluation results of heat resistance at 230° C. and 300° C. However, heat resistance when heat treatment is performed at a higher temperature is not evaluated at all. The same is true for PTL 4.

Meanwhile, PTL 5 described above discloses that the whole or part of a dissolved element in an Al alloy thin film is precipitated as a metal compound by heat treatment at 100° C. to 600° C. to provide an Al alloy thin film having an electrical resistance of 10 μΩcm or less. However, in an example, results when heat treatment is performed at up to 500° C. are just described. Heat resistance when the film is exposed to a high temperature of 500° C. or higher is not evaluated. Needless to say, heat resistance when the film is repeatedly exposed to such a high temperature is not considered at all.

### CITATION LIST

### Patent Literature

PTL 1: Japanese Unexamined Patent Application Publication No. 2007-157917
PTL 2: Japanese Unexamined Patent Application Publication No. 2007-81385
PTL 3: Japanese Unexamined Patent Application Publication No. 2006-210477
PTL 4: Japanese Unexamined Patent Application Publication No. 2007-317934
PTL 5: Japanese Unexamined Patent Application Publication No. 7-90552

### SUMMARY OF INVENTION

### Technical Problem

Recently, it has been desirable to provide an Al alloy film having excellent heat resistance even when heat treatment is performed at high temperatures. This is because there is an increasing need to maximize carrier mobility, which significantly affects the performance of a TFT, in a semiconductor silicon layer to achieve energy savings and higher performance (for example, support for moving images) of a liquid crystal display. To that end, it is necessary to crystallize amorphous hydrogenated silicon serving as a constituent material of the semiconductor silicon layer. Electron mobility in silicon is about three times the hole mobility. Continuous grain silicon has an electron mobility of about 300 cm²/V·s, polycrystalline silicon has an electron mobility of about 100 cm²/V·s, and amorphous hydrogenated silicon has an electron mobility of about 1 cm²/V·s or less. In the case where amorphous hydrogenated silicon is deposited and then subjected to heat treatment, the amorphous hydrogenated silicon becomes microcrystalline to improve carrier mobility. With respect to the heat treatment, a higher heating temperature and a longer heating time allow the microcrystallization of amorphous hydrogenated silicon to proceed, thereby improving the carrier mobility. However, a higher temperature of the heat treatment causes a problem of the formation of an abnormal protrusion (hillock) on an Al alloy wiring thin film due to thermal stress. Hitherto, the upper limit of the temperature of the heat treatment when the Al alloy thin film is used has thus been at most about 350° C. Hence, when heat treatment is performed at a higher temperature than the temperature, a thin film composed of a refractory metal, such as Mo, is commonly used. However, the thin film has a problem in which it does not respond to an increase in the size of a display because of its high wiring resistance.

In addition to the foregoing high-temperature heat resistance, an Al alloy film for use in a display device is required to have various properties. An increase in the amount of an alloying element contained in the Al alloy film increases the electrical resistance of the wiring. The Al alloy film is thus required to have a sufficiently low electrical resistance even if heat treatment is performed at a high temperature, such as about 450° C. to about 600° C.

The Al alloy film is also required to have a low contact resistance (contact resistance) when it is directly connected to a transparent pixel electrode.

Furthermore, the Al alloy film is required to have excellent corrosion resistance. In particular, in a production process of a TFT substrate, a plurality of wet processes are performed. The addition of a more electropositive metal than Al causes a problem of galvanic corrosion, thereby degrading the corrosion resistance. For example, an alkaline developer containing tetramethylammonium hydroxide (TMAH) is used in a photolithography step. In the case of a direct contact structure, a barrier metal layer is omitted, so that the Al alloy film is exposed and easily damaged by the developer. Thus, the Al alloy film is required to have excellent alkaline corrosion resistance, such as resistance to the alkaline developer.

In a wet cleaning step of stripping a photoresist (photosensitive resin) formed in the photolithography step, wet cleaning is continuously performed with an organic stripping solution containing amine. However, the mixing of amine and water forms an alkaline solution. This causes another problem in which Al corrodes in a short time. Meanwhile, the Al alloy is subjected to heat treatment in a chemical vapor deposition (CVD) step before the wet cleaning step. An alloy component forms a precipitate in an Al matrix during the heat treatment. There is a large potential difference between the precipitate and Al. The instant the amine in the stripping solution dips into water, alkaline corrosion proceeds by the galvanic corrosion. Al, which is electrochemically negative, is ionized to migrate, thereby disadvantageously causing pitting corrosion (it looks like black spots). Thus, the Al alloy film is preferably required to have excellent resistance to the stripping solution used to strip the photosensitive resin.

The present invention has been made in light of the circumstances described above. It is an object of the present invention to provide an Al alloy film for use in a display device, the Al alloy film having excellent high-temperature heat resistance such that a hillock is not formed even when the Al alloy film is exposed to a high temperature of about 450° C. to about 600° C., and having low electrical resistance (wiring resistance) and excellent resistance to alkaline corrosion, such as resistance to an organic alkaline developer. It is another object of the present invention to provide an Al alloy film for use in a display device, in which the Al alloy film preferably has excellent resistance to a stripping solution used for a photosensitive resin (stripping solution resistance) and low contact resistance when it is in direct contact (direct contact) with a transparent pixel electrode (transparent conductive film) without using a barrier metal layer and can be directly connected to the transparent conductive film.

### Solution to Problem

The present invention includes aspects described below.

[1] An Al alloy film for use in a display device includes

at least one element selected from group X consisting of Ta, Nb, Re, Zr, W, Mo, V, Hf, Ti, Cr, and Pt; and at least one rare-earth element,

in which when the Al alloy film is subjected to heat treatment at 450° C. to 600° C., the Al alloy film satisfies requirement (1) described below,

(1) first precipitates each containing Al, at least one element selected from group X, and at least one rare-earth element and each having an equivalent circle diameter of 20 nm or more are present at a density of 500,000 particles/mm² or more.
[2] The Al alloy film for use in a display device described in [1] further includes at least one of Cu and Ge, in which when the Al alloy film is subjected to heat treatment at 450° C. to 600° C., the Al alloy film further satisfies requirement (2) described below,
(2) second precipitates each containing Al, at least one of Cu and Ge, and at least one of the rare-earth element and each having an equivalent circle diameter of 200 nm or more are present at a density of 10,000 particles/mm² or more.
[3] The Al alloy film for use in a display device described in [1] further includes at least one of Ni and Co, in which when the Al alloy film is subjected to heat treatment at 450° C. to 600° C., the Al alloy film further satisfies requirement (3) described below,
(3) third precipitates each containing Al, at least one of Ni and Co, at least one of Cu and Ge, and at least one of the rare-earth element and each having an equivalent circle diameter of 200 nm or more are present at a density of 2,000 particles/mm² or more.
[4] In the Al alloy film for use in a display device described in [1], each of the first precipitates has an equivalent circle diameter of 1 μm or less.
[5] In the Al alloy film for use in a display device described in [2] or [3], each of the second precipitates has an equivalent circle diameter of 1 μm or less.
[6] In the Al alloy film for use in a display device described in [2] or [3], each of the third precipitates has an equivalent circle diameter of 3 μm or less.
[7] In the Al alloy film for use in a display device described in any one of [1] to [6], the proportion of the element in group X is in the range of 0.1 to 5 atomic percent.
[8] In the Al alloy film for use in a display device described in any one of [1] to [7], the proportion of the rare-earth element is in the range of 0.1 to 4 atomic percent.
[9] In the Al alloy film for use in a display device described in any one of [2] to [8], the proportion of the at least one of Cu and Ge is in the range of 0.1 to 2 atomic percent.
[10] In the Al alloy film for use in a display device described in any one of [3] to [9], the proportion of the at least one of Ni and Co is in the range of 0.1 to 3 atomic percent.
[11] In the Al alloy film for use in a display device described in any one of [1] to [10], the temperature of the heat treatment is 500° C. to 600° C.
[12] In the Al alloy film for use in a display device described in any one of [1] to [11], the heat treatment is performed at least twice.
[13] In the Al alloy film for use in a display device described in any one of [2] to [12], the Al alloy film is directly connected to a transparent conductive film.
[14] In the Al alloy film for use in a display device described in any one of [1] to [13], the Al alloy film is connected to a transparent conductive film with a film containing at least one element selected from the group consisting of Mo, Ti, W, and Cr.
[15] A sputtering target contains 0.1 to 5 atomic percent of at least one element selected from group X consisting of Ta, Nb, Re, Zr, W, Mo, V, Hf, Ti, Cr, and Pt, 0.1 to 4 atomic percent of at least one rare-earth element, and the balance being Al and incidental impurities.
[16] The sputtering target described in [15] further contains 0.1 to 2 atomic percent of at least one of Cu and Ge.
[17] The sputtering target described in [15] or [16] further contains 0.1 to 3 atomic percent of at least one of Ni and Co.
[18] A display device includes the Al alloy film for use in a display device described in any one of [1] to [14].
[19] A liquid crystal display includes the Al alloy film for use in a display device described in any one of [1] to [14].
[20] An organic electroluminescent (EL) display includes the Al alloy film for use in a display device described in any one of [1] to [14].
[21] A field emission display includes the Al alloy film for use in a display device described in any one of [1] to [14].
[22] A vacuum fluorescent display includes the Al alloy film for use in a display device described in any one of [1] to [14].
[23] A plasma display includes the Al alloy film for use in a display device described in any one of [1] to [14].
[24] An inorganic electroluminescent (EL) display includes the Al alloy film for use in a display device described in any one of [1] to [14].

### Advantageous Effects of Invention

A first Al alloy film (Al-group X element-rare-earth element alloy) according to the present invention is composed of predetermined alloy elements and a first precipitate. Thus, the first Al alloy film has excellent heat resistance when exposed to a high temperature of about 450° C. to about 600° C., and has satisfactory resistance to alkaline corrosion and low electrical resistance (wiring resistance) after high-temperature treatment. Preferably, a second Al alloy film (Al-group X element-rare-earth element-Cu/Ge alloy) according to the present invention is composed of predetermined alloy elements, the first precipitate, and a second precipitate. Thus, the second Al alloy film has higher heat resistance. More preferably, a third Al alloy film (Al-group X element-rare-earth element-Ni/Co—Cu/Ge alloy) according to the present invention is composed of predetermined alloy elements, the first precipitate, the second precipitate, and a third precipitate. Thus, high stripping solution resistance under the high temperature described above and low contact resistance with a transparent conductive film can be provided in addition to the foregoing properties. It is therefore possible to directly connect the Al alloy film to the transparent conductive film.

According to the present invention, in particular, in a process for producing a thin-film transistor substrate including semiconductor layers composed of polycrystalline silicon and continuous grain silicon, when the substrate is exposed to a harsh high-temperature environment in which high-temperature heat treatment at about 450° C. to about 600° C. is performed and even when the high-temperature heat treatment is performed at least twice, carrier mobilities in the semiconductor silicon layers are increased, thereby improving the response speed of a TFT. It is thus possible to provide a high-performance display device that can achieve power savings and support high-speed moving images.

### BRIEF DESCRIPTION OF DRAWINGS

FIG. 1 is a planar transmission electron microscope (TEM) micrograph (magnification: ×30,000) of an Al alloy film (thickness=300 nm) represented by No. 16 (A1-0.1Ni-0.5Ge-2La-0.5Ta) in Table 1, the Al alloy film having been subjected to heat treatment at 600° C. for 10 minutes.

FIG. 2 is an enlarged photograph (magnification: ×60,000) of a portion surrounded by a solid line in FIG. 1.

FIG. 3 is an enlarged photograph (magnification: ×150,000) of a portion surrounded by a solid line in FIG. 2.

FIG. 4 is an enlarged photograph (magnification: ×150,000) of a portion surrounded by a dotted line in FIG. 2.

FIG. 5 illustrates a cross-sectional structure of a core portion of a thin film transistor.

FIG. 6 illustrates a Kelvin pattern (TEG pattern) used for the measurement of the contact resistance between an Al alloy film and a transparent pixel electrode.

FIGS. 7(a) to 7(f) are surface analysis photographs by EDX of precipitates illustrated in FIGS. 3 and 4 (FIG. 3: precipitate 1 and precipitate 2; and FIG. 4: precipitate 3).

FIG. 8 is a schematic cross-sectional view of an exemplary liquid crystal display.

FIG. 9 is a schematic cross-sectional view of an exemplary organic electroluminescent (EL) display.

FIG. 10 is a schematic cross-sectional view of an exemplary field emission display.

FIG. 11 is a schematic cross-sectional view of an exemplary vacuum fluorescent display.

FIG. 12 is a schematic cross-sectional view of an exemplary plasma display.

FIG. 13 is a schematic cross-sectional view of an exemplary inorganic electroluminescent (EL) display.

### DESCRIPTION OF EMBODIMENTS

The inventors have conducted intensive studies in order to provide an Al alloy film (also referred to as a first Al alloy film) for use in a display device, the All alloy film having excellent high-temperature heat resistance such that a hillock is not formed even when the film is repeatedly exposed to a high temperature of about 450° C. to 600° C., and having low electrical resistance (wiring resistance) and high resistance to alkaline corrosion; preferably, to provide an Al alloy film (also referred to as a second Al alloy film) for a display device, the Al alloy film having higher high-temperature heat resistance; and more preferably, to provide an Al alloy film (also referred to as a third Al alloy film) for a display device, the Al alloy film also having excellent resistance to stripping solution at a high temperature and being capable of establishing direct contact (direct contact) with a transparent conductive film because a low contact resistance between the Al alloy film and the transparent conductive film is obtained when the Al alloy film is directly connected to the transparent conductive film.

It was found that a first Al alloy film (Al-group X-REM alloy film) which contains at least one element selected from the group (group X) consisting of Ta, Nb, Re, Zr, W, Mo, V, Hf, Ti, Cr, and Pt and at least one rare-earth element (REM) and which satisfies requirement (1) described below when heat treatment is performed at 450° C. to 600° C., solves the foregoing issues (high heat resistance to high-temperature treatment, low electrical resistance, and high resistance to an organic alkaline developer),

(1) first precipitates each containing Al, at least one element selected from group X described above, and at least one rare-earth element and each having an equivalent circle diameter of 20 nm or more are present at a density of 500,000 particles/mm² or more.

Furthermore, it was found that a second Al alloy film (Al-group X element-REM-Cu/Ge alloy film) which further contains Cu and/or Ge and which satisfies requirement

(1) described above and requirement (2) described below when heat treatment is performed at 450° C. to 600° C., has higher heat resistance,
(2) second precipitates each containing Al, Cu and/or Ge, and at least one rare-earth element and each having an equivalent circle diameter of 200 nm or more are present at a density of 10,000 particles/mm² or more.

Moreover, It was found that a third Al alloy film (Al-group X element-REM-Ni/Co—Cu/Ge alloy film) which contains Ni and/or Co and which satisfies requirements (1) and (2) described above and requirement (3) described below when heat treatment is performed at 450° C. to 600° C., solves not only the foregoing issues but also preferred issues (high resistance to a stripping solution during high-temperature heat treatment and contact resistance with a transparent conductive film).

(3) third precipitates each containing Al, Ni and/or Co, Cu and/or Ge, and at least one rare-earth element and each having an equivalent circle diameter of 200 nm or more are present at a density of 2,000 particles/mm² or more.

The first Al alloy film contains a group X element (an element that improves high-temperature heat resistance), which is a refractory metal, and a rare-earth element (an element that improves resistance to alkaline corrosion) in an Al alloy and the first precipitates. Hence, the first Al alloy film has high heat resistance at high temperatures (high-temperature heat resistance), high resistance to alkaline corrosion, and excellent electrical resistance (wiring resistance), and thus is suitably used as a material for wiring, such as scan lines and signal lines, and electrodes, such as gate electrodes, source electrodes, and drain electrodes. In particular, the first Al alloy film is suitably used as a gate electrode and a material for a relevant wiring film in a thin film transistor substrate that is susceptible to high-temperature heat treatment.

The second Al alloy film contains the group X element, the rare-earth element, and Cu and/or Ge (an element that improves resistance to a stripping solution) in an Al alloy and the predetermined second precipitates. Hence, the second Al alloy film has higher heat resistance at high temperatures (high-temperature heat resistance) and thus is suitably used as a material for wiring, such as scan lines and signal lines, and electrodes, such as gate electrodes, source electrodes, and drain electrodes. In particular, the second Al alloy film is suitably used as a gate electrode and a material for a relevant wiring film in a thin film transistor substrate that is susceptible to high-temperature heat treatment.

The third Al alloy film contains the group X element, the rare-earth element, Ni and/or Co (an element that improves contact resistance with a transparent conductive film), and Cu and/or Ge (an element that improves resistance to a stripping solution) in an Al alloy and the predetermined third precipitates. Hence, the third Al alloy film is suitably used as a material for an electrode and wiring that can come into direct contact with a transparent conductive film without using a barrier metal layer.

In this specification, high-temperature heat resistance indicates that a hillock is not formed when the Al alloy film is exposed to a high temperature of at least about 450° C. to about 600° C., and preferably indicates that a hillock is not formed even when the Al alloy film is repeatedly exposed to the foregoing high temperature at least twice.

In the present invention, the Al alloy film has properties, such as high resistance (corrosion resistance) to chemical solutions (an organic alkaline developer and a stripping solution) used in a production process of a display device, low contact resistance with a transparent conductive film, and low electrical resistance in addition to high-temperature heat resistance. The Al alloy film is characterized in that these properties are provided not only in the low-temperature range of less than 450° C. but also in the foregoing high-temperature range. Note that in a process for fabricating a TFT, the Al alloy film is exposed to an alkaline environment at a stage before the film is subjected to heat treatment. In examples described below, the Al alloy film before heating was examined for resistance to an organic alkaline developer. According to the present invention, experimental results demonstrate that the Al alloy film after high-temperature heat treatment also has satisfactory resistance to the alkaline developer. Incidentally, resistance to the alkaline developer (alkaline developer resistance) is broadly referred to as resistance to alkaline corrosion, in some cases.

The Al alloy film used in the present invention will be described in detail below.

### (First Al Alloy Film)

The first Al alloy film is an Al-group X element-REM alloy film that contains at least one element selected from group X consisting of Ta, Nb, Re, Zr, W, Mo, V, Hf, Ti, Cr, and Pt and at least one rare-earth element (REM).

Here, the elements in group X described above are refractory metals each having a melting point of about 1600° C. or higher and each contribute to improvement in heat resistance at high temperatures. These elements may be added alone or in combination of two or more. Among group X elements, Ta and Ti are preferred. Ta is more preferred.

The proportion of the group X element (when one of the elements is added, the proportion is based on the amount of the element contained; and when two or more of the elements are added, the proportion is based on the total amount of the elements) is preferably in the range of 0.1 to 5 atomic percent. A proportion of the group X element of less than 0.1 atomic percent may not effectively result in the foregoing effects. A proportion of the group X element exceeding 5 atomic percent may result in an excessive increase in the electrical resistance of the Al alloy film itself and may cause a problem in which, for example, residues are easily formed during a wiring process. The proportion of the group X element is more preferably in the range of 0.1 atomic percent to 3.0 atomic percent and still more preferably 0.3 atomic percent to 2.0 atomic percent.

The rare-earth element (REM) is an element that contributes to improvement in high-temperature heat resistance by the addition of the rare-earth element in combination with the group X element. Furthermore, the rare-earth element has a corrosion resistance effect itself in an alkaline environment. The group X element does not have the effect.

Here, the rare-earth element indicates an element group including Sc (scandium) and Y (yttrium) in addition to lanthanoid elements (a total of 15 elements from La with an atomic number of 57 to Lu with an atomic number of 71 in the periodic table). In the present invention, the rare-earth elements may be used alone or in combination of two or more. Among the rare-earth elements, Nd, La, and Gd are preferred. Nd and La are more preferred.

To effectively provide the effect of the rare-earth element, the proportion of the rare-earth element (when one of the elements is added, the proportion is based on the amount of the element contained; and when two or more of the elements are added, the proportion is based on the total amount of the elements) is preferably in the range of 0.1 to 4 atomic percent. A proportion of the rare-earth element of less than 0.1 atomic percent may not effectively provide the resistance to alkaline corrosion. A proportion of the rare-earth element exceeding 4 atomic percent may result in an excessive increase in the electrical resistance of the Al alloy film itself and may cause a problem in which, for example, residues are easily formed during a wiring process. The proportion of the rare-earth element is more preferably in the range of 0.3 atomic percent to 3.0 atomic percent and still more preferably 0.5 atomic percent to 2.5 atomic percent.

An example of the first Al alloy film is an Al alloy film containing the foregoing elements and the balance being Al and incidental impurities.

Here, examples of the incidental impurities include Fe, Si, and B. The total amount of the incidental impurities is not particularly limited and may be contained in an amount of about 0.5 atomic percent or less. With respect to each of the incidental impurities, B may be contained in an amount of 0.012 atomic percent or less. Fe and Si each may be contained in an amount of 0.12 atomic percent or less.

Furthermore, the first Al alloy film contains the first precipitates (Al-group X element-REM-containing precipitates) having the predetermined size and the predetermined density specified in requirement (1) described above by high-temperature heat treatment at 450° C. to 600° C., thereby improving high-temperature heat resistance and preventing the formation of a hillock in a high-temperature process. The first precipitates may contain at least the group X element and the REM. Another element may be contained as long as it does not inhibit the effect of the precipitates.

The first precipitates each have an equivalent circle diameter (size) of 20 nm or more. The results of studies by the inventors demonstrated that precipitates each having an equivalent circle diameter of less than 20 nm do not provide the intended effect even if the precipitates each have an Al-group X element-REM composition. To effectively provide the effect of improving the high-temperature heat resistance, the lower limit of the equivalent circle diameter may be 20 nm. The upper limit of the equivalent circle diameter is not particularly limited in relation to the foregoing effect. In the case where the size of the precipitates is increased to form coarse precipitates, the precipitates can be visually observed by inspection with an optical microscope, thus leading to poor appearance. Thus, the upper limit of the equivalent circle diameter is preferably 1 μm. Each of the first precipitates preferably has an equivalent circle diameter of 20 nm to 800 nm.

Furthermore, in the present invention, the precipitates each having an equivalent circle diameter of 20 nm or more need to be present at a density of 500,000 particles/mm² or more. The results of studies by the inventors demonstrated that in the case where the first precipitates are present at a density of less than 500,000 particles/mm², the intended effect is not provided even if the first precipitates each have a size of 20 nm or more. To effectively provide the effect of improving the high-temperature heat resistance, the precipitates are preferably present at a higher density. The precipitates are preferably present at a density of 2,000,000 particles/mm² or more.

### (Second All Alloy Film)

The second Al alloy film is an Al-group X element-REM-Cu/Ge alloy film that contains the group X element, the rare-earth element (REM), and Cu and/or Ge.

Here, Cu and/or Ge contributes to improvement in high-temperature heat resistance and has the effect of preventing the formation of a hillock in a high-temperature process. The second Al alloy film may contain at least the group X element, the REM, and Cu and/or Ge. Another element may be contained as long as it does not inhibit the effect of these additive elements. Cu and/or Ge may be added separately. Alternatively, both of them may be added.

To effectively provide the effect, the proportion of Cu and/or Ge (when one of the elements is added, the proportion is based on the amount of the element contained; and when both of the elements are added, the proportion is based on the total amount of the elements) is preferably in the range of 0.1 to 2 atomic percent. A proportion of Cu and/or Ge of less than 0.1 atomic percent may not provide the intended effect and may not ensure the density of the second precipitates that contribute to further improvement in heat resistance. A proportion of Cu and/or Ge exceeding 2 atomic percent may result in an increase in electrical resistivity. The proportion of the element is more preferably in the range of 0.1 atomic percent to 1.0 atomic percent and still more preferably 0.1 atomic percent to 0.6 atomic percent.

Furthermore, the second Al alloy film contains the second precipitates (Al-REM-Cu/Ge-containing precipitates) having the predetermined size and the predetermined density specified in requirement (2) described above by high-temperature heat treatment at 450° C. to 600° C., thereby achieving high resistance to a stripping solution at high temperatures and low contact resistance with a transparent conductive film. The second precipitates may contain at least the rare-earth element; and Cu and/or Ge. Another element may be contained as long as it does not inhibit the effect of the precipitates.

The second precipitates each have an equivalent circle diameter (size) of 200 nm or more. The results of studies by the inventors demonstrated that precipitates each having an equivalent circle diameter of less than 200 nm do not provide the intended effect even if the precipitates each satisfy the foregoing composition. To effectively provide the foregoing effect, the lower limit of the equivalent circle diameter may be 200 nm. The upper limit of the equivalent circle diameter is not particularly limited in relation to the foregoing effect. In the case where the size of the precipitates is increased to form coarse precipitates, the precipitates can be visually observed by inspection with an optical microscope, leading to poor appearance. Thus, the upper limit of the equivalent circle diameter is preferably 1 μm. Each of the second precipitates preferably has an equivalent circle diameter of 200 nm to 800 nm.

Furthermore, in the present invention, the precipitates each having an equivalent circle diameter of 200 nm or more need to be present at a density of 10,000 particles/mm² or more. The results of studies by the inventors demonstrated that in the case where the second precipitates are present at a density of less than 10,000 particles/mm², the intended effect is not provided even if the second precipitates each have a size of 200 nm or more. To effectively provide both of the effect of improving the resistance to a stripping solution and the effect of reducing the contact resistance with the transparent conductive film, the precipitates are preferably present at a higher density. The precipitates are preferably present at a density of 25,000 particles/mm² or more.

An example of the second Al alloy film is an Al alloy film containing the foregoing elements and the balance being Al and incidental impurities.

Here, examples of the incidental impurities include Fe, Si, and B. The total amount of the incidental impurities is not particularly limited and may be contained in an amount of about 0.5 atomic percent or less. With respect to each of the incidental impurities, B may be contained in an amount of 0.012 atomic percent or less. Fe and Si each may be contained in an amount of 0.12 atomic percent or less.

### (Third Al Alloy Film)

The third Al alloy film is an Al-group X element-REM-Ni/Co—Cu/Ge alloy film that contains the group X element, the rare-earth element (REM), Cu and/or Ge, and Ni and/or Co.

Here, Ni and Co are elements that enable the Al alloy film to come into direct contact with a transparent conductive film. This is because electrical continuity between the Al alloy film and the transparent conductive film can be established with highly conductive Ni and/or Co-containing Al-based precipitates formed by heat treatment in a process for fabricating a TFT. They may be added separately. Alternatively, both of them may be added.

To effectively provide the effect, the proportion of Ni and/or Co (when one of the elements is added, the proportion is based on the amount of the element contained; and when both of the elements are added, the proportion is based on the total amount of the elements) is preferably in the range of 0.1 to 3 atomic percent. A proportion of Ni and/or Co of less than 0.1 atomic percent may not provide the intended effect and may not ensure the density of the third precipitates that contribute to a reduction in the contact resistance with the transparent conductive film. That is, the size of the third precipitates is small, and the density is low. It is thus difficult to stably maintain low contact resistance with the transparent conductive film. A proportion of Ni and/or Co exceeding 3 atomic percent may result in a reduction in contact resistance in an alkaline environment. The proportion of Ni and/or Co is more preferably in the range of 0.1 atomic percent to 1.0 atomic percent and still more preferably 0.1 atomic percent to 0.6 atomic percent.

Cu and/or Ge is an element that enables the Al alloy film to come into direct contact (direct contact) with the transparent conductive film when Cu and/or Ge is used in combination with Ni and/or Co described above. Thereby, the intended third precipitates can be ensured.

Furthermore, the third Al alloy film contains the third precipitates (Al-REM-Ni/Co—Cu/Ge-containing precipitates) having the predetermined size and the predetermined density specified in requirement (3) described above by high-temperature heat treatment at 450° C. to 600° C., thereby achieving high resistance to a stripping solution at high temperatures and low contact resistance with the transparent conductive film. The third precipitates may contain at least the rare-earth element; Ni and/or Co; and Cu and/or Ge. Another element may be contained as long as it does not inhibit the effect of the precipitates.

The third precipitates each have an equivalent circle diameter (size) of 200 nm or more. The results of studies by the inventors demonstrated that precipitates each having an equivalent circle diameter of less than 200 nm do not provide the intended effect even if the precipitates each satisfy the foregoing composition. To effectively provide the foregoing effect, the lower limit of the equivalent circle diameter may be 200 nm. The upper limit of the equivalent circle diameter is not particularly limited in relation to the foregoing effect. In the case where the size of the precipitates is increased to form coarse precipitates, the precipitates can be visually observed by inspection with an optical microscope, thus leading to poor appearance. Thus, the upper limit of the equivalent circle diameter is preferably 3 μm. Each of the third precipitates preferably has an equivalent circle diameter of 200 nm to 2 μm.

Furthermore, in the present invention, the precipitates each having an equivalent circle diameter of 200 nm or more need to be present at a density of 2000 particles/mm² or more. The results of studies by the inventors demonstrated that in the case where the third precipitates are present at a density of less than 2000 particles/mm², the intended effect is not provided even if the third precipitates each have a size of 200 nm or more. To effectively provide both of the effect of improving the resistance to a stripping solution and the effect of reducing the contact resistance with the transparent conductive film, the precipitates are preferably present at a higher density. The precipitates are preferably present at a density of 5000 particles/mm² or more.

An example of the third Al alloy film is an Al alloy film containing the foregoing elements and the balance being Al and incidental impurities.

Here, examples of the incidental impurities include Fe, Si, and B. The total amount of the incidental impurities is not particularly limited and may be contained in an amount of about 0.5 atomic percent or less. With respect to each of the incidental impurities, B may be contained in an amount of 0.012 atomic percent or less. Fe and Si each may be contained in an amount of 0.12 atomic percent or less.

The Al alloy film according to the present invention has been described above.

In the present invention, heat treatment to form the first to third precipitates described above is in the range of 450° C. to 600° C. and preferably 500° C. to 600° C. The heat treatment is preferably performed in vacuum or in a nitrogen and/or inert gas atmosphere. The treatment time is preferably in the range of 1 minute to 60 minutes. According to the present invention, it was found that even if the foregoing heat treatment (high-temperature heat treatment) is performed two or more, a hillock and so forth are not formed.

Examples of a TFT production process corresponding to the high-temperature heat treatment include annealing by, for example, a laser for crystallization of amorphous silicon; the formation of a film by chemical vapor deposition (CVD) used for the formation of various thin films; and the temperature of a heat treatment furnace during impurity diffusion and heat curing of a protective film. In particular, the Al alloy film is often exposed to the foregoing high temperature when subjected to heat treatment for crystallization of amorphous silicon.

In particular, to ensure high-temperature heat resistance and a reduction in wiring resistance, the Al alloy film preferably has a thickness of 50 nm or more and more preferably 100 nm or more. The upper limit of the thickness is not particularly limited from the point of view described above. In view of the tapered shape of wiring, the upper limit of the thickness is preferably 1 μm or less and more preferably 600 nm or less. The range of the thickness may be determined by any combination of the upper limit and the lower limit.

The Al alloy film is preferably used for various wiring materials, such as source-drain electrodes and a gate electrode. In particular, the Al alloy film is more preferably used as a wiring material for a gate electrode required to have high-temperature heat resistance.

The Al alloy film is preferably formed by a sputtering method with a sputtering target (hereinafter, also referred to as a “target”) because a thin film having excellent in-plane uniformity in components and thickness can be easily formed, compared with the case where a thin film is formed by an ion-plating method, an electron-beam evaporation method, or a vacuum evaporation method.

In the case where the Al alloy film is formed by the sputtering method, an Al alloy sputtering target containing the foregoing elements and having a composition the same as the composition of a desired Al alloy film is suitably used as the target because the use of the target eliminates composition deviation and results in the formation of an Al alloy film having an intended composition.

In the present invention, sputtering targets having the same compositions as the first, second, and third Al alloy films are also included in the scope of the present invention. Specifically, the targets include (i) a target containing 0.1 to 5 atomic percent of at least one element selected from the group (group X) consisting of Ta, Nb, Re, Zr, W, Mo, V, Hf, Ti, Cr, and Pt, 0.1 to 4 atomic percent of at least one rare-earth element, and the balance being Al and incidental impurities; (ii) a target containing 0.1 to 5 atomic percent of at least one element selected from the group (group X) consisting of Ta, Nb, Re, Zr, W, Mo, V, Hf, Ti, Cr, and Pt, 0.1 to 4 atomic percent of at least one rare-earth element, 0.1 to 2 atomic percent of Cu and/or Ge, and the balance being Al and incidental impurities; and (iii) a target containing 0.1 to 5 atomic percent of at least one element selected from the group (group X) consisting of Ta, Nb, Re, Zr, W, Mo, V, Hf, Ti, Cr, and Pt, 0.1 to 4 atomic percent of at least one rare-earth element, 0.1 to 2 atomic percent of Cu and/or Ge, 0.1 to 3 atomic percent of Ni and/or Co, and the balance being Al and incidental impurities.

With respect to the shape of the target, the target may be processed into any shape (a square plate-like shape, a circular plate-like shape, a doughnut plate-like shape, a cylinder shape, or the like) corresponding to the shape and structure of a sputtering apparatus.

Examples of a method for producing the target include a method in which an ingot composed of an Al-base alloy is produced by a melt-casting process, a powder sintering process, or a spray forming process to form a target; and a method in which after a preform (intermediate before the final dense product) composed of an Al-based alloy is produced, the preform is densified by densification means to form a target.

The present invention includes a display device characterized in that the Al alloy film is used for a thin film transistor. Examples of an embodiment of the present invention include an embodiment in which the Al alloy films are used for a source electrode and/or a drain electrode of the thin film transistor, and a signal line, and in which the drain electrode is directly connected to a transparent conductive film; and an embodiment in which the Al alloy films are used for a gate electrode and a scan line. In the case where the first and second Al alloy films are used, the Al alloy films are preferably connected to the transparent conductive film with a refractory metal film or a refractory alloy film (barrier metal) containing at least one element selected from the group consisting of Mo, Ti, W, and Cr. In the case where the third Al alloy film is used, preferably, the Al alloy film is directly connected to the transparent conductive film without using the barrier metal.

Furthermore, the case where the gate electrode, the scan line, the source electrode and/or the drain electrode, and the signal line are formed of the Al alloy film having the same composition is included as an embodiment.

A transparent pixel electrode used in the present invention is not particularly limited. Examples thereof include indium tin oxide (ITO) and indium zinc oxide (IZO).

A semiconductor layer used in the present invention is not particularly limited. Examples thereof include amorphous silicon, polycrystalline silicon, and continuous grain silicon.

To produce the display device including the Al alloy film of the present invention, a common process for producing a display device may be employed. For example, the production methods described in PTLs 1 to 5 described above may be referenced.

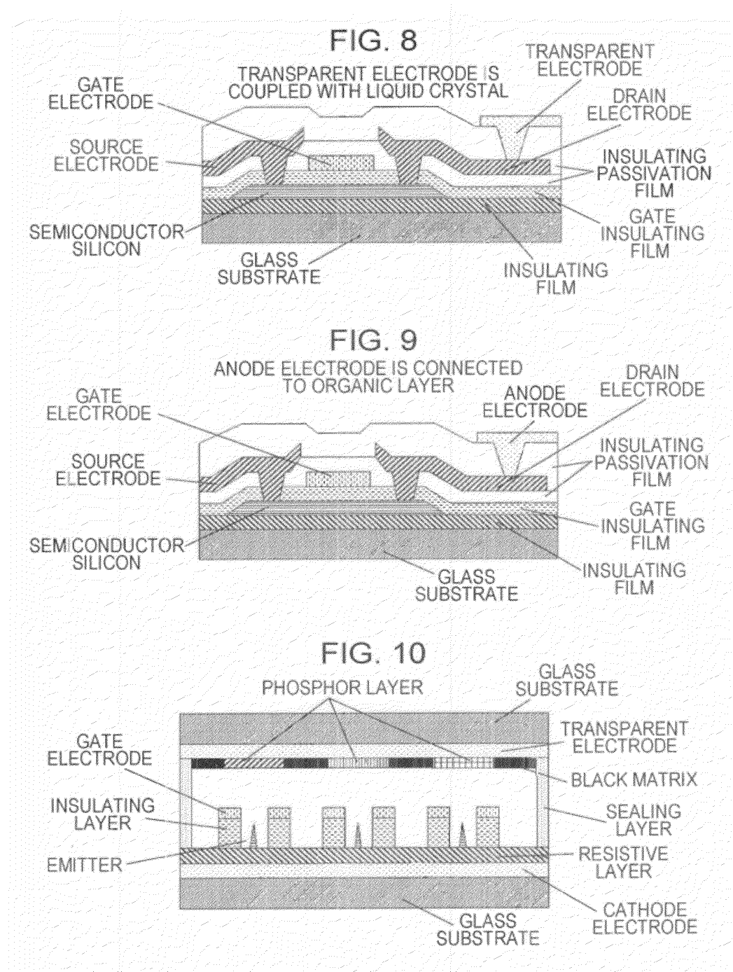

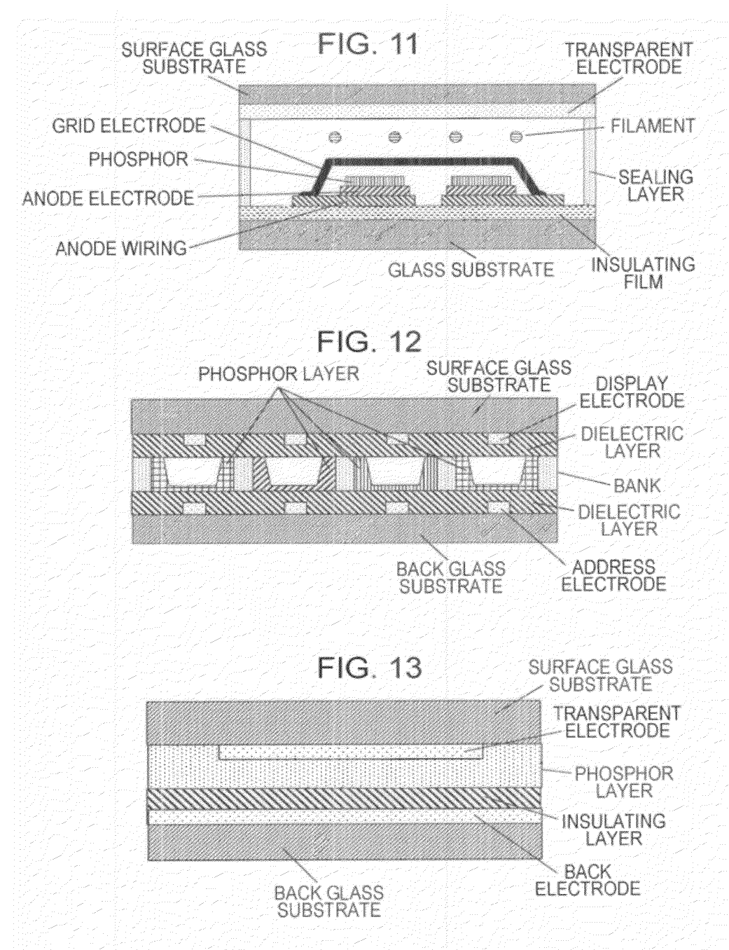

As a liquid crystal display device, a liquid crystal display has been representatively described above. The foregoing Al alloy film for use in a display device according to the present invention may be mainly used as electrodes and wiring materials in various liquid crystal display devices. Examples of the electrodes and wiring materials include gate, source, and drain electrodes for a thin film transistor and a wiring material in a liquid crystal display (LDC) as illustrated in FIG. 8; gate, source, and drain electrodes for a thin film transistor and a wiring material in an organic EL (OELD) as illustrated in FIG. 9; cathode and gate electrodes and a wiring material in a field emission display (FED) as illustrated in FIG. 10; an anode electrode and a wiring material in a vacuum fluorescent display (VFD) as illustrated in FIG. 11; an address electrode and a wiring material in a plasma display (PDP) as illustrated in FIG. 12; and a back electrode in an inorganic EL as illustrated in FIG. 13. Our experimental results demonstrate that in the case where the Al alloy film for use in a display device according to the present invention is used for these liquid crystal display devices, the predetermined effects described above are provided.

### EXAMPLES

The present invention will be more specifically described below by examples. The present invention is not limited to these examples described below. The present invention may be modified and performed without departing from the spirit of the present invention described above and below. They are also within the technical scope of the present invention.

### Example 1

Al alloy films (thickness: 300 nm) having various alloy compositions described in Tables 1 to 7 were formed by a DC magnetron sputtering method (substrate: glass substrate (Eagle 2000, manufactured by Corning Inc.), atmospheric gas: argon, pressure: 2 mTorr, and substrate temperature: 25° C. (room temperature)).

In the formation of the Al alloy films having various alloy compositions, Al alloy targets having various compositions produced by a vacuum melting method were used.

Proportions of alloy elements in various Al alloy films used in the examples were determined by inductively coupled plasma spectrometry (ICP).

Each Al alloy film formed as described above was subjected to high-temperature heat treatment twice at 450° C. to 600° C. With respect to each of the Al alloy films after the high-temperature heat treatment, properties of heat resistance, the electrical resistance (wiring resistance) of the Al alloy film itself, contact resistance (contact resistance with ITO) when the Al alloy film was directly connected to a transparent pixel electrode, and resistance to a stripping solution, and the size and density of precipitates were measured by methods described below. For the purpose of reference, with respect to heat resistance, an experiment at 350° C. was also performed. With respect to resistance to an organic alkaline developer, an experiment was made on an as-deposited Al alloy film without heat treatment. This is because in a TFT fabrication process, the Al alloy film is exposed to an alkaline environment in a photolithography step of forming Al alloy wiring before subjected to heat treatment.

(1) Heat Resistance after Heat Treatment

Each as-deposited Al alloy film was subjected to heat treatment twice in an inert (N₂) gas atmosphere at temperatures described in Tables 1 to 7 for 10 minutes for each heat treatment. The surface properties of the films were observed with an optical microscope (magnification: ×500) to measure the density of hillocks (particles/m²). The heat resistance was evaluated according to evaluation criteria described in Table 8. In this example, ⊙ or ◯ indicates that the corresponding films were acceptable.

(2) Wiring Resistance of al Alloy Film after Heat Treatment

A 10 μm line-and-space pattern formed on each of the as-deposited Al alloy films was subjected to heat treatment twice in an inert (N₂) gas atmosphere at 450° C., 550° C., or 600° C. for 10 minutes for each heat treatment. The electrical resistance was measured by a four-terminal method. The wiring resistance for each temperature was evaluated according to evaluation criteria described in Table 8. In this example, 0 or 0 indicates that the corresponding films were acceptable.

(3) Direct Contact Resistance with Transparent Pixel Electrode

Each as-deposited Al alloy film was subjected to heat treatment twice in an inert (N₂) gas atmosphere at 600° C. for 10 minutes for each heat treatment. The contact resistance when the resulting Al alloy film was in direct contact with a transparent pixel electrode was measured as follows: A Kelvin pattern (contact hole size: 10 μm×10 μm square) illustrated in FIG. 6 was formed as the transparent pixel electrode (indium tin oxide (ITO): indium oxide containing 10% by mass tin oxide) by sputtering under conditions described below, and a four-terminal measurement (a current was passed between ITO and the Al alloy film, and a voltage drop between ITO and the Al alloy was measured with other terminals) was performed. Specifically, a current I was passed between I₁ and I₂ in FIG. 6, and a voltage V between V₁ and V₂ was monitored. A direct contact resistance R at contact hole C was calculated from the expression [R=(V₂−V₁)/I₂]. The direct contact resistance with ITO (contact resistance with ITO) was evaluated according to evaluation criteria described in Table 8. In this example, ⊙ or ◯ indicates that the corresponding films were acceptable.

(Deposition Conditions of Transparent Pixel Electrode)

Atmospheric gas: argon

Pressure: 0.8 mTorr

Substrate temperature: 25° C. (room temperature)

### (4) Resistance to Organic Alkaline Developer (Measurement of Etch Rate in Developer)

After a mask was formed on each Al alloy film formed on the substrate, the Al alloy film was immersed in a developer (an aqueous solution containing 2.38% by mass TMAH) at 25° C. for 5 minutes. The amount etched was measured with a profilometer. The resistance to the alkaline developer was evaluated according to evaluation criteria described in Table 8. In this example, 0 or 0 indicates that the corresponding films were acceptable.

### (5) Resistance to Stripping Solution

A corrosion experiment with an alkaline dilution containing an amine-based photoresist and water was performed in a manner simulating a wet cleaning step with a photoresist stripping solution. Specifically, each as-deposited Al alloy film was subjected to heat treatment twice in an inert (N₂) gas atmosphere at 600° C. for 20 minutes for each heat treatment and then immersed in aqueous amine-based resist stripping solutions (TOK 106, manufactured by Tokyo Ohka Kogyo Co., Ltd.) with pH values adjusted to 10.5 and 9.5 (solution temperature: 25° C.). Specifically, the film was immersed in the solution with a pH of 10.5 for 1 minute and consecutively immersed in the solution with a pH of 9.5 for 5 minutes. The number of crater-like corrosion (pitting corrosion) marks (each having an equivalent circle diameter of 150 nm or more) observed on a surface of the film after immersion was studied (observation magnification: ×1000). The resistance to the stripping solution was evaluated according to evaluation criteria described in Table 8. In this example, ⊙ or ◯ indicates that the corresponding films were acceptable.

### (6) Measurement of Precipitate

Each as-deposited Al alloy film was subjected to heat treatment twice in an inert (N₂) gas atmosphere at 550° C. or 600° C. for 10 minutes for each heat treatment. The resulting precipitates were observed with a planar transmission electron microscope (TEM, magnification: ×300,000). The size (equivalent circle diameter) and the density (particles/mm²) of the precipitates were determined on the basis of reflection electron images obtained with a scanning electron microscope. Specifically, the equivalent circle diameters and the number of precipitates observed in one field of view (mm²) were measured, and the mean values in three fields of view were determined. Elements in the precipitates were identified by TEM-EDX analysis. The size and the density of the precipitates were classified according to evaluation criteria described in Table 8. Precipitates that meet the size requirement represented by ⊙, ◯, or Δ and the density requirement represented by ⊙ or ◯ satisfy the requirement of the present invention.

Tables 1 to 7 summarize the results.

TABLE 1

| | | Precipitate | | Precipitate | | | | | |
|---|---|---|---|---|---|---|---|---|---|
| | Composition of Al alloy film | size | | density | | Heat resistance | | | |
| No. | (balance: Al and incidental impurities) | 550° C. | 600° C. | 550° C. | 600° C. | 350° C. | 450° C. | 550° C. | 600° C. |
| 1 | Al—0.1 at % Ta—0.3 at % Nd—0.1 at % Ni—0.5 at % Ge | ⊙ | ⊙ | ◯ | ◯ | ⊙ | ⊙ | ◯ | ◯ |
| 2 | Al—0.1 at % Ta—0.3 at % La—0.1 at % Ni—0.5 at % Ge | ⊙ | ⊙ | ◯ | ◯ | ⊙ | ⊙ | ◯ | ◯ |
| 3 | Al—0.1 at % Ta—0.6 at % Nd—0.1 at % Ni—0.5 at % Ge | ⊙ | ⊙ | ◯ | ◯ | ⊙ | ⊙ | ◯ | ◯ |
| 4 | Al—0.1 at % Ta—0.6 at % La—0.1 at % Ni—0.5 at % Ge | ⊙ | ⊙ | ◯ | ◯ | ⊙ | ⊙ | ◯ | ◯ |
| 5 | Al—0.1 at % Ta—2.0 at % Nd—0.1 at % Ni—0.5 at % Ge | ⊙ | ⊙ | ◯ | ◯ | ⊙ | ⊙ | ◯ | ◯ |
| 6 | Al—0.1 at % Ta—2.0 at % La—0.1 at % Ni—0.5 at % Ge | ⊙ | ⊙ | ◯ | ◯ | ⊙ | ⊙ | ◯ | ◯ |
| 7 | Al—0.1 at % Ta—3.0 at % Nd—0.1 at % Ni—0.5 at % Ge | ⊙ | ⊙ | ◯ | ◯ | ⊙ | ⊙ | ◯ | ◯ |
| 8 | Al—0.1 at % Ta—3.0 at % La—0.1 at % Ni—0.5 at % Ge | ⊙ | ⊙ | ◯ | ◯ | ⊙ | ⊙ | ◯ | ◯ |
| 9 | Al—0.1 at % Ta—0.3 at % Nd—0.1 at % Ni—0.5 at % Cu | ⊙ | ⊙ | ◯ | ◯ | ⊙ | ⊙ | ◯ | ◯ |
| 10 | Al—0.1 at % Ta—0.3 at % La—0.1 at % Ni—0.5 at % Cu | ⊙ | ⊙ | ◯ | ◯ | ⊙ | ⊙ | ◯ | ◯ |
| 11 | Al—0.1 at % Ta—0.6 at % Nd—0.1 at % Ni—0.5 at % Cu | ⊙ | ⊙ | ◯ | ◯ | ⊙ | ⊙ | ◯ | ◯ |
| 12 | Al—0.1 at % Ta—0.6 at % La—0.1 at % Ni—0.5 at % Cu | ⊙ | ⊙ | ◯ | ◯ | ⊙ | ⊙ | ◯ | ◯ |
| 13 | Al—0.1 at % Ta—2.0 at % Nd—0.1 at % Ni—0.5 at % Cu | ⊙ | ⊙ | ◯ | ◯ | ⊙ | ⊙ | ◯ | ◯ |
| 14 | Al—0.1 at % Ta—2.0 at % La—0.1 at % Ni—0.5 at % Cu | ⊙ | ⊙ | ◯ | ◯ | ⊙ | ⊙ | ◯ | ◯ |
| 15 | Al—0.1 at % Ta—3.0 at % Nd—0.1 at % Ni—0.5 at % Cu | ⊙ | ⊙ | ◯ | ◯ | ⊙ | ⊙ | ◯ | ◯ |
| 16 | Al—0.1 at % Ta—3.0 at % La—0.1 at % Ni—0.5 at % Cu | ⊙ | ⊙ | ◯ | ◯ | ⊙ | ⊙ | ◯ | ◯ |
| 17 | Al—0.1 at % Ta—0.3 at % Nd—0.1 at % Co—0.5 at % Ge | ⊙ | ⊙ | ◯ | ◯ | ⊙ | ⊙ | ◯ | ◯ |
| 18 | Al—0.1 at % Ta—0.3 at % La—0.1 at % Co—0.5 at % Ge | ⊙ | ⊙ | ◯ | ◯ | ⊙ | ⊙ | ◯ | ◯ |
| 19 | Al—0.1 at % Ta—0.6 at % Nd—0.1 at % Co—0.5 at % Ge | ⊙ | ⊙ | ◯ | ◯ | ⊙ | ⊙ | ◯ | ◯ |
| 20 | Al—0.1 at % Ta—0.6 at % La—0.1 at % Co—0.5 at % Ge | ⊙ | ⊙ | ◯ | ◯ | ⊙ | ⊙ | ◯ | ◯ |
| 21 | Al—0.1 at % Ta—2.0 at % Nd—0.1 at % Co—0.5 at % Ge | ⊙ | ⊙ | ◯ | ◯ | ⊙ | ⊙ | ◯ | ◯ |
| 22 | Al—0.1 at % Ta—2.0 at % La—0.1 at % Co—0.5 at % Ge | ⊙ | ⊙ | ◯ | ◯ | ⊙ | ⊙ | ◯ | ◯ |
| 23 | Al—0.1 at % Ta—3.0 at % Nd—0.1 at % Co—0.5 at % Ge | ⊙ | ⊙ | ◯ | ◯ | ⊙ | ⊙ | ◯ | ◯ |
| 24 | Al—0.1 at % Ta—3.0 at % La—0.1 at % Co—0.5 at % Ge | ⊙ | ⊙ | ◯ | ◯ | ⊙ | ⊙ | ◯ | ◯ |

| | | | | | | | Resistance to |
|---|---|---|---|---|---|---|---|
| | | | | | Contact | Resistance | organic |
| | | | | | resistance | to stripping | alkaline |
| | Composition of Al alloy film | Wiring resistance | | | with ITO | solution | developer |
| No. | (balance: Al and incidental impurities) | 450° C. | 550° C. | 600° C. | 600° C. | 600° C. | — |
| 1 | Al—0.1 at % Ta—0.3 at % Nd—0.1 at % Ni—0.5 at % Ge | ⊙ | ⊙ | ⊙ | ⊙ | ⊙ | ⊙ |
| 2 | Al—0.1 at % Ta—0.3 at % La—0.1 at % Ni—0.5 at % Ge | ⊙ | ⊙ | ⊙ | ⊙ | ⊙ | ⊙ |
| 3 | Al—0.1 at % Ta—0.6 at % Nd—0.1 at % Ni—0.5 at % Ge | ⊙ | ⊙ | ⊙ | ⊙ | ⊙ | ⊙ |
| 4 | Al—0.1 at % Ta—0.6 at % La—0.1 at % Ni—0.5 at % Ge | ⊙ | ⊙ | ⊙ | ⊙ | ⊙ | ⊙ |
| 5 | Al—0.1 at % Ta—2.0 at % Nd—0.1 at % Ni—0.5 at % Ge | ⊙ | ⊙ | ⊙ | ⊙ | ⊙ | ⊙ |
| 6 | Al—0.1 at % Ta—2.0 at % La—0.1 at % Ni—0.5 at % Ge | ⊙ | ⊙ | ⊙ | ⊙ | ⊙ | ⊙ |
| 7 | Al—0.1 at % Ta—3.0 at % Nd—0.1 at % Ni—0.5 at % Ge | ⊙ | ⊙ | ⊙ | ⊙ | ⊙ | ⊙ |
| 8 | Al—0.1 at % Ta—3.0 at % La—0.1 at % Ni—0.5 at % Ge | ⊙ | ⊙ | ⊙ | ⊙ | ⊙ | ⊙ |
| 9 | Al—0.1 at % Ta—0.3 at % Nd—0.1 at % Ni—0.5 at % Cu | ⊙ | ⊙ | ⊙ | ⊙ | ⊙ | ⊙ |
| 10 | Al—0.1 at % Ta—0.3 at % La—0.1 at % Ni—0.5 at % Cu | ⊙ | ⊙ | ⊙ | ⊙ | ⊙ | ⊙ |
| 11 | Al—0.1 at % Ta—0.6 at % Nd—0.1 at % Ni—0.5 at % Cu | ⊙ | ⊙ | ⊙ | ⊙ | ⊙ | ⊙ |
| 12 | Al—0.1 at % Ta—0.6 at % La—0.1 at % Ni—0.5 at % Cu | ⊙ | ⊙ | ⊙ | ⊙ | ⊙ | ⊙ |
| 13 | Al—0.1 at % Ta—2.0 at % Nd—0.1 at % Ni—0.5 at % Cu | ⊙ | ⊙ | ⊙ | ⊙ | ⊙ | ⊙ |
| 14 | Al—0.1 at % Ta—2.0 at % La—0.1 at % Ni—0.5 at % Cu | ⊙ | ⊙ | ⊙ | ⊙ | ⊙ | ⊙ |
| 15 | Al—0.1 at % Ta—3.0 at % Nd—0.1 at % Ni—0.5 at % Cu | ⊙ | ⊙ | ⊙ | ⊙ | ⊙ | ⊙ |
| 16 | Al—0.1 at % Ta—3.0 at % La—0.1 at % Ni—0.5 at % Cu | ⊙ | ⊙ | ⊙ | ⊙ | ⊙ | ⊙ |
| 17 | Al—0.1 at % Ta—0.3 at % Nd—0.1 at % Co—0.5 at % Ge | ⊙ | ⊙ | ⊙ | ⊙ | ⊙ | ⊙ |
| 18 | Al—0.1 at % Ta—0.3 at % La—0.1 at % Co—0.5 at % Ge | ⊙ | ⊙ | ⊙ | ⊙ | ⊙ | ⊙ |
| 19 | Al—0.1 at % Ta—0.6 at % Nd—0.1 at % Co—0.5 at % Ge | ⊙ | ⊙ | ⊙ | ⊙ | ⊙ | ⊙ |
| 20 | Al—0.1 at % Ta—0.6 at % La—0.1 at % Co—0.5 at % Ge | ⊙ | ⊙ | ⊙ | ⊙ | ⊙ | ⊙ |
| 21 | Al—0.1 at % Ta—2.0 at % Nd—0.1 at % Co—0.5 at % Ge | ⊙ | ⊙ | ⊙ | ⊙ | ⊙ | ⊙ |
| 22 | Al—0.1 at % Ta—2.0 at % La—0.1 at % Co—0.5 at % Ge | ⊙ | ⊙ | ⊙ | ⊙ | ⊙ | ⊙ |
| 23 | Al—0.1 at % Ta—3.0 at % Nd—0.1 at % Co—0.5 at % Ge | ⊙ | ⊙ | ⊙ | ⊙ | ⊙ | ⊙ |
| 24 | Al—0.1 at % Ta—3.0 at % La—0.1 at % Co—0.5 at % Ge | ⊙ | ⊙ | ⊙ | ⊙ | ⊙ | ⊙ |

TABLE 2

| | | Precipitate | | Precipitate | | | | | |
|---|---|---|---|---|---|---|---|---|---|
| | Composition of Al alloy film | size | | density | | Heat resistance | | | |
| No. | (balance: Al and incidental impurities) | 550° C. | 600° C. | 550° C. | 600° C. | 350° C. | 450° C. | 550° C. | 600° C. |
| 25 | Al—0.25 at % Ta—0.3 at % Nd—0.1 at % Ni—0.5 at % Ge | ⊙ | ⊙ | ⊙ | ⊙ | ⊙ | ⊙ | ⊙ | ◯ |
| 26 | Al—0.25 at % Ta—0.3 at % La—0.1 at % Ni—0.5 at % Ge | ⊙ | ⊙ | ⊙ | ⊙ | ⊙ | ⊙ | ⊙ | ◯ |
| 27 | Al—0.25 at % Ta—0.6 at % Nd—0.1 at % Ni—0.5 at % Ge | ⊙ | ⊙ | ⊙ | ⊙ | ⊙ | ⊙ | ⊙ | ◯ |
| 28 | Al—0.25 at % Ta—0.6 at % La—0.1 at % Ni—0.5 at % Ge | ⊙ | ⊙ | ⊙ | ⊙ | ⊙ | ⊙ | ⊙ | ◯ |
| 29 | Al—0.25 at % Ta—2.0 at % Nd—0.1 at % Ni—0.5 at % Ge | ⊙ | ⊙ | ⊙ | ⊙ | ⊙ | ⊙ | ⊙ | ◯ |
| 30 | Al—0.25 at % Ta—2.0 at % La—0.1 at % Ni—0.5 at % Ge | ⊙ | ⊙ | ⊙ | ⊙ | ⊙ | ⊙ | ⊙ | ◯ |
| 31 | Al—0.25 at % Ta—2.0 at % Gd—0.1 at % Ni—0.5 at % Ge | ⊙ | ⊙ | ⊙ | ⊙ | ⊙ | ⊙ | ⊙ | ◯ |
| 32 | Al—0.25 at % Ta—2.0 at % Y—0.1 at % Ni—0.5 at % Ge | ⊙ | ⊙ | ⊙ | ⊙ | ⊙ | ⊙ | ⊙ | ◯ |
| 33 | Al—0.25 at % Ta—2.0 at % Ce—0.1 at % Ni—0.5 at % Ge | ⊙ | ⊙ | ⊙ | ⊙ | ⊙ | ⊙ | ⊙ | ◯ |
| 34 | Al—0.25 at % Ta—2.0 at % Sc—0.1 at % Ni—0.5 at % Ge | ⊙ | ⊙ | ⊙ | ⊙ | ⊙ | ⊙ | ⊙ | ◯ |
| 35 | Al—0.25 at % Ta—2.0 at % Dy—0.1 at % Ni—0.5 at % Ge | ⊙ | ⊙ | ⊙ | ⊙ | ⊙ | ⊙ | ⊙ | ◯ |
| 36 | Al—0.25 at % Ta—3.0 at % Nd—0.1 at % Ni—0.5 at % Ge | ⊙ | ⊙ | ⊙ | ⊙ | ⊙ | ⊙ | ⊙ | ◯ |
| 37 | Al—0.25 at % Ta—3.0 at % La—0.1 at % Ni—0.5 at % Ge | ⊙ | ⊙ | ⊙ | ⊙ | ⊙ | ⊙ | ⊙ | ◯ |
| 38 | Al—0.5 at % Ta—0.3 at % Nd—0.1 at % Ni—0.5 at % Ge | ⊙ | ⊙ | ⊙ | ⊙ | ⊙ | ⊙ | ⊙ | ⊙ |
| 39 | Al—0.5 at % Ta—0.3 at % La—0.1 at % Ni—0.5 at % Ge | ⊙ | ⊙ | ⊙ | ⊙ | ⊙ | ⊙ | ⊙ | ⊙ |
| 40 | Al—0.5 at % Ta—0.6 at % Nd—0.1 at % Ni—0.5 at % Ge | ⊙ | ⊙ | ⊙ | ⊙ | ⊙ | ⊙ | ⊙ | ⊙ |
| 41 | Al—0.5 at % Ta—0.6 at % La—0.1 at % Ni—0.5 at % Ge | ⊙ | ⊙ | ⊙ | ⊙ | ⊙ | ⊙ | ⊙ | ⊙ |
| 42 | Al—0.5 at % Ta—2.0 at % Nd—0.1 at % Ni—0.5 at % Ge | ⊙ | ⊙ | ⊙ | ⊙ | ⊙ | ⊙ | ⊙ | ⊙ |
| 43 | Al—0.5 at % Ta—2.0 at % La—0.1 at % Ni—0.5 at % Ge | ⊙ | ⊙ | ⊙ | ⊙ | ⊙ | ⊙ | ⊙ | ⊙ |
| 44 | Al—0.5 at % Ta—2.0 at % Gd—0.1 at % Ni—0.5 at % Ge | ⊙ | ⊙ | ⊙ | ⊙ | ⊙ | ⊙ | ⊙ | ⊙ |
| 45 | Al—0.5 at % Ta—2.0 at % Y—0.1 at % Ni—0.5 at % Ge | ⊙ | ⊙ | ⊙ | ⊙ | ⊙ | ⊙ | ⊙ | ⊙ |
| 46 | Al—0.5 at % Ta—2.0 at % Ce—0.1 at % Ni—0.5 at % Ge | ⊙ | ⊙ | ⊙ | ⊙ | ⊙ | ⊙ | ⊙ | ⊙ |
| 47 | Al—0.5 at % Ta—2.0 at % Sc—0.1 at % Ni—0.5 at % Ge | ⊙ | ⊙ | ⊙ | ⊙ | ⊙ | ⊙ | ⊙ | ⊙ |
| 48 | Al—0.5 at % Ta—2.0 at % Dy—0.1 at % Ni—0.5 at % Ge | ⊙ | ⊙ | ⊙ | ⊙ | ⊙ | ⊙ | ⊙ | ⊙ |
| 49 | Al—0.5 at % Ta—3.0 at % Nd—0.1 at % Ni—0.5 at % Ge | ⊙ | ⊙ | ⊙ | ⊙ | ⊙ | ⊙ | ⊙ | ⊙ |
| 50 | Al—0.5 at % Ta—3.0 at % La—0.1 at % Ni—0.5 at % Ge | ⊙ | ⊙ | ⊙ | ⊙ | ⊙ | ⊙ | ⊙ | ⊙ |
| 51 | Al—0.5 at % Ta—0.3 at % Nd—0.1 at % Co—0.5 at % Ge | ⊙ | ⊙ | ⊙ | ⊙ | ⊙ | ⊙ | ⊙ | ⊙ |
| 52 | Al—0.5 at % Ta—0.3 at % La—0.1 at % Co—0.5 at % Ge | ⊙ | ⊙ | ⊙ | ⊙ | ⊙ | ⊙ | ⊙ | ⊙ |

| | | | | | | | Resistance to |
|---|---|---|---|---|---|---|---|
| | | | | | Contact | Resistance | organic |
| | | | | | resistance | to stripping | alkaline |
| | Composition of Al alloy film | Wiring resistance | | | with ITO | solution | developer |
| No. | (balance: Al and incidental impurities) | 450° C. | 550° C. | 600° C. | 600° C. | 600° C. | — |
| 25 | Al—0.25 at % Ta—0.3 at % Nd—0.1 at % Ni—0.5 at % Ge | ⊙ | ⊙ | ⊙ | ⊙ | ⊙ | ⊙ |
| 26 | Al—0.25 at % Ta—0.3 at % La—0.1 at % Ni—0.5 at % Ge | ⊙ | ⊙ | ⊙ | ⊙ | ⊙ | ⊙ |
| 27 | Al—0.25 at % Ta—0.6 at % Nd—0.1 at % Ni—0.5 at % Ge | ⊙ | ⊙ | ⊙ | ⊙ | ⊙ | ⊙ |
| 28 | Al—0.25 at % Ta—0.6 at % La—0.1 at % Ni—0.5 at % Ge | ⊙ | ⊙ | ⊙ | ⊙ | ⊙ | ⊙ |
| 29 | Al—0.25 at % Ta—2.0 at % Nd—0.1 at % Ni—0.5 at % Ge | ⊙ | ⊙ | ⊙ | ⊙ | ⊙ | ⊙ |
| 30 | Al—0.25 at % Ta—2.0 at % La—0.1 at % Ni—0.5 at % Ge | ⊙ | ⊙ | ⊙ | ⊙ | ⊙ | ⊙ |
| 31 | Al—0.25 at % Ta—2.0 at % Gd—0.1 at % Ni—0.5 at % Ge | ⊙ | ⊙ | ⊙ | ⊙ | ⊙ | ⊙ |
| 32 | Al—0.25 at % Ta—2.0 at % Y—0.1 at % Ni—0.5 at % Ge | ⊙ | ⊙ | ⊙ | ⊙ | ⊙ | ⊙ |
| 33 | Al—0.25 at % Ta—2.0 at % Ce—0.1 at % Ni—0.5 at % Ge | ⊙ | ⊙ | ⊙ | ⊙ | ⊙ | ⊙ |
| 34 | Al—0.25 at % Ta—2.0 at % Sc—0.1 at % Ni—0.5 at % Ge | ⊙ | ⊙ | ⊙ | ⊙ | ⊙ | ⊙ |
| 35 | Al—0.25 at % Ta—2.0 at % Dy—0.1 at % Ni—0.5 at % Ge | ⊙ | ⊙ | ⊙ | ⊙ | ⊙ | ⊙ |
| 36 | Al—0.25 at % Ta—3.0 at % Nd—0.1 at % Ni—0.5 at % Ge | ⊙ | ⊙ | ⊙ | ⊙ | ⊙ | ⊙ |
| 37 | Al—0.25 at % Ta—3.0 at % La—0.1 at % Ni—0.5 at % Ge | ⊙ | ⊙ | ⊙ | ⊙ | ⊙ | ⊙ |
| 38 | Al—0.5 at % Ta—0.3 at % Nd—0.1 at % Ni—0.5 at % Ge | ⊙ | ⊙ | ⊙ | ⊙ | ⊙ | ⊙ |
| 39 | Al—0.5 at % Ta—0.3 at % La—0.1 at % Ni—0.5 at % Ge | ⊙ | ⊙ | ⊙ | ⊙ | ⊙ | ⊙ |
| 40 | Al—0.5 at % Ta—0.6 at % Nd—0.1 at % Ni—0.5 at % Ge | ⊙ | ⊙ | ⊙ | ⊙ | ⊙ | ⊙ |
| 41 | Al—0.5 at % Ta—0.6 at % La—0.1 at % Ni—0.5 at % Ge | ⊙ | ⊙ | ⊙ | ⊙ | ⊙ | ⊙ |
| 42 | Al—0.5 at % Ta—2.0 at % Nd—0.1 at % Ni—0.5 at % Ge | ⊙ | ⊙ | ⊙ | ⊙ | ⊙ | ⊙ |
| 43 | Al—0.5 at % Ta—2.0 at % La—0.1 at % Ni—0.5 at % Ge | ⊙ | ⊙ | ⊙ | ⊙ | ⊙ | ⊙ |
| 44 | Al—0.5 at % Ta—2.0 at % Gd—0.1 at % Ni—0.5 at % Ge | ⊙ | ⊙ | ⊙ | ⊙ | ⊙ | ⊙ |
| 45 | Al—0.5 at % Ta—2.0 at % Y—0.1 at % Ni—0.5 at % Ge | ⊙ | ⊙ | ⊙ | ⊙ | ⊙ | ⊙ |
| 46 | Al—0.5 at % Ta—2.0 at % Ce—0.1 at % Ni—0.5 at % Ge | ⊙ | ⊙ | ⊙ | ⊙ | ⊙ | ⊙ |
| 47 | Al—0.5 at % Ta—2.0 at % Sc—0.1 at % Ni—0.5 at % Ge | ⊙ | ⊙ | ⊙ | ⊙ | ⊙ | ⊙ |
| 48 | Al—0.5 at % Ta—2.0 at % Dy—0.1 at % Ni—0.5 at % Ge | ⊙ | ⊙ | ⊙ | ⊙ | ⊙ | ⊙ |
| 49 | Al—0.5 at % Ta—3.0 at % Nd—0.1 at % Ni—0.5 at % Ge | ⊙ | ⊙ | ⊙ | ⊙ | ⊙ | ⊙ |
| 50 | Al—0.5 at % Ta—3.0 at % La—0.1 at % Ni—0.5 at % Ge | ⊙ | ⊙ | ⊙ | ⊙ | ⊙ | ⊙ |
| 51 | Al—0.5 at % Ta—0.3 at % Nd—0.1 at % Co—0.5 at % Ge | ⊙ | ⊙ | ⊙ | ⊙ | ⊙ | ⊙ |
| 52 | Al—0.5 at % Ta—0.3 at % La—0.1 at % Co—0.5 at % Ge | ⊙ | ⊙ | ⊙ | ⊙ | ⊙ | ⊙ |

TABLE 3

| | | Precipitate | | Precipitate | | | | | |
|---|---|---|---|---|---|---|---|---|---|
| | Composition of Al alloy film | size | | density | | Heat resistance | | | |
| No. | (balance: Al and incidental impurities) | 550° C. | 600° C. | 550° C. | 600° C. | 350° C. | 450° C. | 550° C. | 600° C. |
| 53 | Al—0.5 at % Ta—0.6 at % La—0.1 at % Co—0.5 at % Ge | ⊙ | ⊙ | ⊙ | ⊙ | ⊙ | ⊙ | ⊙ | ⊙ |
| 54 | Al—0.5 at % Ta—2.0 at % Nd—0.1 at % Co—0.5 at % Ge | ⊙ | ⊙ | ⊙ | ⊙ | ⊙ | ⊙ | ⊙ | ⊙ |
| 55 | Al—0.5 at % Ta—2.0 at % La—0.1 at % Co—0.5 at % Ge | ⊙ | ⊙ | ⊙ | ⊙ | ⊙ | ⊙ | ⊙ | ⊙ |
| 56 | Al—0.5 at % Ta—3.0 at % Nd—0.1 at % Co—0.5 at % Ge | ⊙ | ⊙ | ⊙ | ⊙ | ⊙ | ⊙ | ⊙ | ⊙ |
| 57 | Al—0.5 at % Ta—3.0 at % La—0.1 at % Co—0.5 at % Ge | ⊙ | ⊙ | ⊙ | ⊙ | ⊙ | ⊙ | ⊙ | ⊙ |
| 58 | Al—0.5 at % Ta—0.3 at % Nd—0.1 at % Ni—0.3 at % Ge | ⊙ | ⊙ | ⊙ | ⊙ | ⊙ | ⊙ | ⊙ | ⊙ |
| 59 | Al—0.5 at % Ta—0.3 at % La—0.1 at % Ni—0.3 at % Ge | ⊙ | ⊙ | ⊙ | ⊙ | ⊙ | ⊙ | ⊙ | ⊙ |
| 60 | Al—0.5 at % Ta—3.0 at % Nd—0.1 at % Ni—0.3 at % Ge | ⊙ | ⊙ | ⊙ | ⊙ | ⊙ | ⊙ | ⊙ | ⊙ |
| 61 | Al—0.5 at % Ta—3.0 at % La—0.1 at % Ni—0.3 at % Ge | ⊙ | ⊙ | ⊙ | ⊙ | ⊙ | ⊙ | ⊙ | ⊙ |
| 62 | Al—0.5 at % Ta—0.3 at % Nd—0.1 at % Ni—1.0 at % Ge | ⊙ | ⊙ | ⊙ | ⊙ | ⊙ | ⊙ | ⊙ | ⊙ |
| 63 | Al—0.5 at % Ta—0.3 at % La—0.1 at % Ni—1.0 at % Ge | ⊙ | ⊙ | ⊙ | ⊙ | ⊙ | ⊙ | ⊙ | ⊙ |
| 64 | Al—0.5 at % Ta—3.0 at % Nd—0.1 at % Ni—1.0 at % Ge | ⊙ | ⊙ | ⊙ | ⊙ | ⊙ | ⊙ | ⊙ | ⊙ |
| 65 | Al—0.5 at % Ta—3.0 at % La—0.1 at % Ni—1.0 at % Ge | ⊙ | ⊙ | ⊙ | ⊙ | ⊙ | ⊙ | ⊙ | ⊙ |
| 66 | Al—0.5 at % Ta—0.3 at % Nd—0.1 at % Ni—2.0 at % Ge | ⊙ | ⊙ | ⊙ | ⊙ | ⊙ | ⊙ | ⊙ | ⊙ |
| 67 | Al—0.5 at % Ta—0.3 at % La—0.1 at % Ni—2.0 at % Ge | ⊙ | ⊙ | ⊙ | ⊙ | ⊙ | ⊙ | ⊙ | ⊙ |
| 68 | Al—0.5 at % Ta—3.0 at % Nd—0.1 at % Ni—2.0 at % Ge | ⊙ | ⊙ | ⊙ | ⊙ | ⊙ | ⊙ | ⊙ | ⊙ |
| 69 | Al—0.5 at % Ta—3.0 at % La—0.1 at % Ni—2.0 at % Ge | ⊙ | ⊙ | ⊙ | ⊙ | ⊙ | ⊙ | ⊙ | ⊙ |
| 70 | Al—0.5 at % Ta—0.3 at % Nd—0.1 at % Ni—0.5 at % Cu | ⊙ | ⊙ | ⊙ | ⊙ | ⊙ | ⊙ | ⊙ | ⊙ |
| 71 | Al—0.5 at % Ta—0.3 at % La—0.1 at % Ni—0.5 at % Cu | ⊙ | ⊙ | ⊙ | ⊙ | ⊙ | ⊙ | ⊙ | ⊙ |
| 72 | Al—0.5 at % Ta—3.0 at % Nd—0.1 at % Ni—0.5 at % Cu | ⊙ | ⊙ | ⊙ | ⊙ | ⊙ | ⊙ | ⊙ | ⊙ |
| 73 | Al—0.5 at % Ta—3.0 at % La—0.1 at % Ni—0.5 at % Cu | ⊙ | ⊙ | ⊙ | ⊙ | ⊙ | ⊙ | ⊙ | ⊙ |
| 74 | Al—0.5 at % Ta—3.0 at % Nd—2.0 at % Ni—0.5 at % Ge | ⊙ | ⊙ | ⊙ | ⊙ | ⊙ | ⊙ | ⊙ | ⊙ |
| 75 | Al—0.5 at % Ta—3.0 at % La—2.0 at % Ni—0.5 at % Ge | ⊙ | ⊙ | ⊙ | ⊙ | ⊙ | ⊙ | ⊙ | ⊙ |

| | | | | | | | Resistance to |
|---|---|---|---|---|---|---|---|
| | | | | | Contact | Resistance | organic |
| | | | | | resistance | to stripping | alkaline |
| | Composition of Al alloy film | Wiring resistance | | | with ITO | solution | developer |
| No. | (balance: Al and incidental impurities) | 450° C. | 550° C. | 600° C. | 600° C. | 600° C. | — |
| 53 | Al—0.5 at % Ta—0.6 at % La—0.1 at % Co—0.5 at % Ge | ⊙ | ⊙ | ⊙ | ⊙ | ⊙ | ⊙ |
| 54 | Al—0.5 at % Ta—2.0 at % Nd—0.1 at % Co—0.5 at % Ge | ⊙ | ⊙ | ⊙ | ⊙ | ⊙ | ⊙ |
| 55 | Al—0.5 at % Ta—2.0 at % La—0.1 at % Co—0.5 at % Ge | ⊙ | ⊙ | ⊙ | ⊙ | ⊙ | ⊙ |
| 56 | Al—0.5 at % Ta—3.0 at % Nd—0.1 at % Co—0.5 at % Ge | ⊙ | ⊙ | ⊙ | ⊙ | ⊙ | ⊙ |
| 57 | Al—0.5 at % Ta—3.0 at % La—0.1 at % Co—0.5 at % Ge | ⊙ | ⊙ | ⊙ | ⊙ | ⊙ | ⊙ |
| 58 | Al—0.5 at % Ta—0.3 at % Nd—0.1 at % Ni—0.3 at % Ge | ⊙ | ⊙ | ⊙ | ⊙ | ⊙ | ⊙ |
| 59 | Al—0.5 at % Ta—0.3 at % La—0.1 at % Ni—0.3 at % Ge | ⊙ | ⊙ | ⊙ | ⊙ | ⊙ | ⊙ |
| 60 | Al—0.5 at % Ta—3.0 at % Nd—0.1 at % Ni—0.3 at % Ge | ⊙ | ⊙ | ⊙ | ⊙ | ⊙ | ⊙ |
| 61 | Al—0.5 at % Ta—3.0 at % La—0.1 at % Ni—0.3 at % Ge | ⊙ | ⊙ | ⊙ | ⊙ | ⊙ | ⊙ |
| 62 | Al—0.5 at % Ta—0.3 at % Nd—0.1 at % Ni—1.0 at % Ge | ⊙ | ⊙ | ⊙ | ⊙ | ⊙ | ⊙ |
| 63 | Al—0.5 at % Ta—0.3 at % La—0.1 at % Ni—1.0 at % Ge | ⊙ | ⊙ | ⊙ | ⊙ | ⊙ | ⊙ |
| 64 | Al—0.5 at % Ta—3.0 at % Nd—0.1 at % Ni—1.0 at % Ge | ⊙ | ⊙ | ⊙ | ⊙ | ⊙ | ⊙ |
| 65 | Al—0.5 at % Ta—3.0 at % La—0.1 at % Ni—1.0 at % Ge | ⊙ | ⊙ | ⊙ | ⊙ | ⊙ | ⊙ |
| 66 | Al—0.5 at % Ta—0.3 at % Nd—0.1 at % Ni—2.0 at % Ge | ⊙ | ⊙ | ⊙ | ⊙ | ⊙ | ⊙ |
| 67 | Al—0.5 at % Ta—0.3 at % La—0.1 at % Ni—2.0 at % Ge | ⊙ | ⊙ | ⊙ | ⊙ | ⊙ | ⊙ |
| 68 | Al—0.5 at % Ta—3.0 at % Nd—0.1 at % Ni—2.0 at % Ge | ⊙ | ⊙ | ⊙ | ⊙ | ⊙ | ⊙ |
| 69 | Al—0.5 at % Ta—3.0 at % La—0.1 at % Ni—2.0 at % Ge | ⊙ | ⊙ | ⊙ | ⊙ | ⊙ | ⊙ |
| 70 | Al—0.5 at % Ta—0.3 at % Nd—0.1 at % Ni—0.5 at % Cu | ⊙ | ⊙ | ⊙ | ⊙ | ⊙ | ⊙ |
| 71 | Al—0.5 at % Ta—0.3 at % La—0.1 at % Ni—0.5 at % Cu | ⊙ | ⊙ | ⊙ | ⊙ | ⊙ | ⊙ |
| 72 | Al—0.5 at % Ta—3.0 at % Nd—0.1 at % Ni—0.5 at % Cu | ⊙ | ⊙ | ⊙ | ⊙ | ⊙ | ⊙ |
| 73 | Al—0.5 at % Ta—3.0 at % La—0.1 at % Ni—0.5 at % Cu | ⊙ | ⊙ | ⊙ | ⊙ | ⊙ | ⊙ |
| 74 | Al—0.5 at % Ta—3.0 at % Nd—2.0 at % Ni—0.5 at % Ge | ⊙ | ⊙ | ⊙ | ◯ | ⊙ | ◯ |
| 75 | Al—0.5 at % Ta—3.0 at % La—2.0 at % Ni—0.5 at % Ge | ⊙ | ⊙ | ⊙ | ◯ | ⊙ | ◯ |

TABLE 4

| | | Precipitate | | Precipitate | | | | | |
|---|---|---|---|---|---|---|---|---|---|
| | Composition of Al alloy film | size | | density | | Heat resistance | | | |
| No. | (balance: Al and incidental impurities) | 550° C. | 600° C. | 550° C. | 600° C. | 350° C. | 450° C. | 550° C. | 600° C. |
| 76 | Al—1.5 at % Ta—0.3 at % Nd—0.1 at % Ni—0.5 at % Ge | ◯ | ◯ | ⊙ | ⊙ | ⊙ | ⊙ | ⊙ | ⊙ |
| 77 | Al—1.5 at % Ta—0.3 at % La—0.1 at % Ni—0.5 at % Ge | ◯ | ◯ | ⊙ | ⊙ | ⊙ | ⊙ | ⊙ | ⊙ |
| 78 | Al—1.5 at % Ta—0.6 at % Nd—0.1 at % Ni—0.5 at % Ge | ◯ | ◯ | ⊙ | ⊙ | ⊙ | ⊙ | ⊙ | ⊙ |
| 79 | Al—1.5 at % Ta—0.6 at % La—0.1 at % Ni—0.5 at % Ge | ◯ | ◯ | ⊙ | ⊙ | ⊙ | ⊙ | ⊙ | ⊙ |
| 80 | Al—1.5 at % Ta—2.0 at % Nd—0.1 at % Ni—0.5 at % Ge | ◯ | ◯ | ⊙ | ⊙ | ⊙ | ⊙ | ⊙ | ⊙ |
| 81 | Al—1.5 at % Ta—2.0 at % La—0.1 at % Ni—0.5 at % Ge | ◯ | ◯ | ⊙ | ⊙ | ⊙ | ⊙ | ⊙ | ⊙ |
| 82 | Al—1.5 at % Ta—2.0 at % Gd—0.1 at % Ni—0.5 at % Ge | ◯ | ◯ | ⊙ | ⊙ | ⊙ | ⊙ | ⊙ | ⊙ |
| 83 | Al—1.5 at % Ta—2.0 at % Y—0.1 at % Ni—0.5 at % Ge | ◯ | ◯ | ⊙ | ⊙ | ⊙ | ⊙ | ⊙ | ⊙ |
| 84 | Al—1.5 at % Ta—2.0 at % Ce—0.1 at % Ni—0.5 at % Ge | ◯ | ◯ | ⊙ | ⊙ | ⊙ | ⊙ | ⊙ | ⊙ |
| 85 | Al—1.5 at % Ta—2.0 at % Sc—0.1 at % Ni—0.5 at % Ge | ◯ | ◯ | ⊙ | ⊙ | ⊙ | ⊙ | ⊙ | ⊙ |
| 86 | Al—1.5 at % Ta—2.0 at % Dy—0.1 at % Ni—0.5 at % Ge | ◯ | ◯ | ⊙ | ⊙ | ⊙ | ⊙ | ⊙ | ⊙ |
| 87 | Al—1.5 at % Ta—3.0 at % Nd—0.1 at % Ni—0.5 at % Ge | ◯ | ◯ | ⊙ | ⊙ | ⊙ | ⊙ | ⊙ | ⊙ |
| 88 | Al—1.5 at % Ta—3.0 at % La—0.1 at % Ni—0.5 at % Ge | ◯ | ◯ | ⊙ | ⊙ | ⊙ | ⊙ | ⊙ | ⊙ |
| 89 | Al—5.0 at % Ta—0.3 at % Nd—0.1 at % Ni—0.5 at % Ge | Δ | Δ | ⊙ | ⊙ | ⊙ | ⊙ | ⊙ | ⊙ |
| 90 | Al—5.0 at % Ta—0.3 at % La—0.1 at % Ni—0.5 at % Ge | Δ | Δ | ⊙ | ⊙ | ⊙ | ⊙ | ⊙ | ⊙ |
| 91 | Al—5.0 at % Ta—3.0 at % Nd—0.1 at % Ni—0.5 at % Ge | Δ | Δ | ⊙ | ⊙ | ⊙ | ⊙ | ⊙ | ⊙ |
| 92 | Al—5.0 at % Ta—3.0 at % La—0.1 at % Ni—0.5 at % Ge | Δ | Δ | ⊙ | ⊙ | ⊙ | ⊙ | ⊙ | ⊙ |
| 93 | Al—5.0 at % Ta—0.3 at % Nd—0.1 at % Co—0.5 at % Ge | Δ | Δ | ⊙ | ⊙ | ⊙ | ⊙ | ⊙ | ⊙ |
| 94 | Al—5.0 at % Ta—0.3 at % La—0.1 at % Co—0.5 at % Ge | Δ | Δ | ⊙ | ⊙ | ⊙ | ⊙ | ⊙ | ⊙ |
| 95 | Al—5.0 at % Ta—3.0 at % Nd—0.1 at % Co—0.5 at % Ge | Δ | Δ | ⊙ | ⊙ | ⊙ | ⊙ | ⊙ | ⊙ |
| 96 | Al—5.0 at % Ta—3.0 at % La—0.1 at % Co—0.5 at % Ge | Δ | Δ | ⊙ | ⊙ | ⊙ | ⊙ | ⊙ | ⊙ |
| 97 | Al—0.5 at % Ti—3.0 at % La—0.1 at % Ni—0.5 at % Ge | ◯ | ◯ | ⊙ | ⊙ | ⊙ | ⊙ | ⊙ | ◯ |
| 98 | Al—0.5 at % Ti—3.0 at % Nd—0.1 at % Ni—0.5 at % Ge | ◯ | ◯ | ⊙ | ⊙ | ⊙ | ⊙ | ⊙ | ◯ |
| 99 | Al—5.0 at % Ti—3.0 at % La—0.1 at % Ni—0.5 at % Ge | Δ | Δ | ⊙ | ⊙ | ⊙ | ⊙ | ⊙ | ⊙ |
| 100 | Al—0.5 at % Nb—3.0 at % Nd—0.1 at % Ni—0.5 at % Ge | ◯ | ◯ | ⊙ | ⊙ | ⊙ | ⊙ | ⊙ | ◯ |

| | | | | | | | Resistance to |
|---|---|---|---|---|---|---|---|
| | | | | | Contact | Resistance | organic |
| | | | | | resistance | to stripping | alkaline |
| | Composition of Al alloy film | Wiring resistance | | | with ITO | solution | developer |
| No. | (balance: Al and incidental impurities) | 450° C. | 550° C. | 600° C. | 600° C. | 600° C. | — |
| 76 | Al—1.5 at % Ta—0.3 at % Nd—0.1 at % Ni—0.5 at % Ge | ◯ | ⊙ | ⊙ | ⊙ | ⊙ | ⊙ |
| 77 | Al—1.5 at % Ta—0.3 at % La—0.1 at % Ni—0.5 at % Ge | ◯ | ⊙ | ⊙ | ⊙ | ⊙ | ⊙ |
| 78 | Al—1.5 at % Ta—0.6 at % Nd—0.1 at % Ni—0.5 at % Ge | ◯ | ⊙ | ⊙ | ⊙ | ⊙ | ⊙ |
| 79 | Al—1.5 at % Ta—0.6 at % La—0.1 at % Ni—0.5 at % Ge | ◯ | ⊙ | ⊙ | ⊙ | ⊙ | ⊙ |
| 80 | Al—1.5 at % Ta—2.0 at % Nd—0.1 at % Ni—0.5 at % Ge | ◯ | ⊙ | ⊙ | ⊙ | ⊙ | ⊙ |
| 81 | Al—1.5 at % Ta—2.0 at % La—0.1 at % Ni—0.5 at % Ge | ◯ | ⊙ | ⊙ | ⊙ | ⊙ | ⊙ |
| 82 | Al—1.5 at % Ta—2.0 at % Gd—0.1 at % Ni—0.5 at % Ge | ◯ | ⊙ | ⊙ | ⊙ | ⊙ | ⊙ |
| 83 | Al—1.5 at % Ta—2.0 at % Y—0.1 at % Ni—0.5 at % Ge | ◯ | ⊙ | ⊙ | ⊙ | ⊙ | ⊙ |
| 84 | Al—1.5 at % Ta—2.0 at % Ce—0.1 at % Ni—0.5 at % Ge | ◯ | ⊙ | ⊙ | ⊙ | ⊙ | ⊙ |
| 85 | Al—1.5 at % Ta—2.0 at % Sc—0.1 at % Ni—0.5 at % Ge | ◯ | ⊙ | ⊙ | ⊙ | ⊙ | ⊙ |
| 86 | Al—1.5 at % Ta—2.0 at % Dy—0.1 at % Ni—0.5 at % Ge | ◯ | ⊙ | ⊙ | ⊙ | ⊙ | ⊙ |
| 87 | Al—1.5 at % Ta—3.0 at % Nd—0.1 at % Ni—0.5 at % Ge | ◯ | ⊙ | ⊙ | ⊙ | ⊙ | ⊙ |
| 88 | Al—1.5 at % Ta—3.0 at % La—0.1 at % Ni—0.5 at % Ge | ◯ | ⊙ | ⊙ | ⊙ | ⊙ | ⊙ |
| 89 | Al—5.0 at % Ta—0.3 at % Nd—0.1 at % Ni—0.5 at % Ge | ◯ | ◯ | ◯ | ⊙ | ⊙ | ⊙ |
| 90 | Al—5.0 at % Ta—0.3 at % La—0.1 at % Ni—0.5 at % Ge | ◯ | ◯ | ◯ | ⊙ | ⊙ | ⊙ |
| 91 | Al—5.0 at % Ta—3.0 at % Nd—0.1 at % Ni—0.5 at % Ge | ◯ | ◯ | ◯ | ⊙ | ⊙ | ⊙ |
| 92 | Al—5.0 at % Ta—3.0 at % La—0.1 at % Ni—0.5 at % Ge | ◯ | ◯ | ◯ | ⊙ | ⊙ | ⊙ |
| 93 | Al—5.0 at % Ta—0.3 at % Nd—0.1 at % Co—0.5 at % Ge | ◯ | ◯ | ◯ | ⊙ | ⊙ | ⊙ |
| 94 | Al—5.0 at % Ta—0.3 at % La—0.1 at % Co—0.5 at % Ge | ◯ | ◯ | ◯ | ⊙ | ⊙ | ⊙ |
| 95 | Al—5.0 at % Ta—3.0 at % Nd—0.1 at % Co—0.5 at % Ge | ◯ | ◯ | ◯ | ⊙ | ⊙ | ⊙ |
| 96 | Al—5.0 at % Ta—3.0 at % La—0.1 at % Co—0.5 at % Ge | ◯ | ◯ | ◯ | ⊙ | ⊙ | ⊙ |
| 97 | Al—0.5 at % Ti—3.0 at % La—0.1 at % Ni—0.5 at % Ge | ⊙ | ⊙ | ⊙ | ⊙ | ⊙ | ⊙ |
| 98 | Al—0.5 at % Ti—3.0 at % Nd—0.1 at % Ni—0.5 at % Ge | ⊙ | ⊙ | ⊙ | ⊙ | ⊙ | ⊙ |
| 99 | Al—5.0 at % Ti—3.0 at % La—0.1 at % Ni—0.5 at % Ge | ◯ | ◯ | ◯ | ⊙ | ⊙ | ⊙ |
| 100 | Al—0.5 at % Nb—3.0 at % Nd—0.1 at % Ni—0.5 at % Ge | ⊙ | ⊙ | ⊙ | ⊙ | ⊙ | ⊙ |

TABLE 5

| | | Precipitate | | Precipitate | | | | | |
|---|---|---|---|---|---|---|---|---|---|
| | Composition of Al alloy film | size | | density | | Heat resistance | | | |
| No. | (balance: Al and incidental impurities) | 550° C. | 600° C. | 550° C. | 600° C. | 350° C. | 450° C. | 550° C. | 600° C. |
| 101 | Al—0.5 at % Nb—3.0 at % La—0.1 at % Ni—0.5 at % Ge | ◯ | ◯ | ⊙ | ⊙ | ⊙ | ⊙ | ⊙ | ◯ |
| 102 | Al—0.5 at % Re—3.0 at % Nd—0.1 at % Ni—0.5 at % Ge | ◯ | ◯ | ⊙ | ⊙ | ⊙ | ⊙ | ⊙ | ◯ |
| 103 | Al—0.5 at % Re—3.0 at % La—0.1 at % Ni—0.5 at % Ge | ◯ | ◯ | ⊙ | ⊙ | ⊙ | ⊙ | ⊙ | ◯ |
| 104 | Al—0.5 at % Zr—3.0 at % Nd—0.1 at % Ni—0.5 at % Ge | ◯ | ◯ | ⊙ | ⊙ | ⊙ | ⊙ | ⊙ | ◯ |
| 105 | Al—0.5 at % Zr—3.0 at % La—0.1 at % Ni—0.5 at % Ge | ◯ | ◯ | ⊙ | ⊙ | ⊙ | ⊙ | ⊙ | ◯ |
| 106 | Al—0.5 at % W—3.0 at % Nd—0.1 at % Ni—0.5 at % Ge | ◯ | ◯ | ⊙ | ⊙ | ⊙ | ⊙ | ⊙ | ◯ |
| 107 | Al—0.5 at % W—3.0 at % La—0.1 at % Ni—0.5 at % Ge | ◯ | ◯ | ⊙ | ⊙ | ⊙ | ⊙ | ⊙ | ◯ |
| 108 | Al—0.5 at % Mo—3.0 at % Nd—0.1 at % Ni—0.5 at % Ge | ◯ | ◯ | ⊙ | ⊙ | ⊙ | ⊙ | ⊙ | ◯ |
| 109 | Al—0.5 at % Mo—3.0 at % La—0.1 at % Ni—0.5 at % Ge | ◯ | ◯ | ⊙ | ⊙ | ⊙ | ⊙ | ⊙ | ◯ |
| 110 | Al—0.5 at % V—3.0 at % Nd—0.1 at % Ni—0.5 at % Ge | ◯ | ◯ | ⊙ | ⊙ | ⊙ | ⊙ | ⊙ | ◯ |
| 111 | Al—0.5 at % V—3.0 at % La—0.1 at % Ni—0.5 at % Ge | ◯ | ◯ | ⊙ | ⊙ | ⊙ | ⊙ | ⊙ | ◯ |
| 112 | Al—0.5 at % Hf—3.0 at % Nd—0.1 at % Ni—0.5 at % Ge | ◯ | ◯ | ⊙ | ⊙ | ⊙ | ⊙ | ⊙ | ◯ |
| 113 | Al—0.5 at % Hf—3.0 at % La—0.1 at % Ni—0.5 at % Ge | ◯ | ◯ | ⊙ | ⊙ | ⊙ | ⊙ | ⊙ | ◯ |
| 114 | Al—0.5 at % Cr—3.0 at % Nd—0.1 at % Ni—0.5 at % Ge | ◯ | ◯ | ⊙ | ⊙ | ⊙ | ⊙ | ⊙ | ◯ |
| 115 | Al—0.5 at % Cr—3.0 at % La—0.1 at % Ni—0.5 at % Ge | ◯ | ◯ | ⊙ | ⊙ | ⊙ | ⊙ | ⊙ | ◯ |
| 116 | Al—0.5 at % Pt—3.0 at % Nd—0.1 at % Ni—0.5 at % Ge | ◯ | ◯ | ⊙ | ⊙ | ⊙ | ⊙ | ⊙ | ◯ |
| 117 | Al—0.5 at % Pt—3.0 at % La—0.1 at % Ni—0.5 at % Ge | ◯ | ◯ | ⊙ | ⊙ | ⊙ | ⊙ | ⊙ | ◯ |

| | | | | | | | Resistance to |
|---|---|---|---|---|---|---|---|
| | | | | | Contact | Resistance | organic |
| | | | | | resistance | to stripping | alkaline |
| | Composition of Al alloy film | Wiring resistance | | | with ITO | solution | developer |
| No. | (balance: Al and incidental impurities) | 450° C. | 550° C. | 600° C. | 600° C. | 600° C. | — |
| 101 | Al—0.5 at % Nb—3.0 at % La—0.1 at % Ni—0.5 at % Ge | ⊙ | ⊙ | ⊙ | ⊙ | ⊙ | ⊙ |
| 102 | Al—0.5 at % Re—3.0 at % Nd—0.1 at % Ni—0.5 at % Ge | ⊙ | ⊙ | ⊙ | ⊙ | ⊙ | ⊙ |
| 103 | Al—0.5 at % Re—3.0 at % La—0.1 at % Ni—0.5 at % Ge | ⊙ | ⊙ | ⊙ | ⊙ | ⊙ | ⊙ |
| 104 | Al—0.5 at % Zr—3.0 at % Nd—0.1 at % Ni—0.5 at % Ge | ⊙ | ⊙ | ⊙ | ⊙ | ⊙ | ⊙ |
| 105 | Al—0.5 at % Zr—3.0 at % La—0.1 at % Ni—0.5 at % Ge | ⊙ | ⊙ | ⊙ | ⊙ | ⊙ | ⊙ |
| 106 | Al—0.5 at % W—3.0 at % Nd—0.1 at % Ni—0.5 at % Ge | ⊙ | ⊙ | ⊙ | ⊙ | ⊙ | ⊙ |
| 107 | Al—0.5 at % W—3.0 at % La—0.1 at % Ni—0.5 at % Ge | ⊙ | ⊙ | ⊙ | ⊙ | ⊙ | ⊙ |
| 108 | Al—0.5 at % Mo—3.0 at % Nd—0.1 at % Ni—0.5 at % Ge | ⊙ | ⊙ | ⊙ | ⊙ | ⊙ | ⊙ |
| 109 | Al—0.5 at % Mo—3.0 at % La—0.1 at % Ni—0.5 at % Ge | ⊙ | ⊙ | ⊙ | ⊙ | ⊙ | ⊙ |
| 110 | Al—0.5 at % V—3.0 at % Nd—0.1 at % Ni—0.5 at % Ge | ⊙ | ⊙ | ⊙ | ⊙ | ⊙ | ⊙ |
| 111 | Al—0.5 at % V—3.0 at % La—0.1 at % Ni—0.5 at % Ge | ⊙ | ⊙ | ⊙ | ⊙ | ⊙ | ⊙ |
| 112 | Al—0.5 at % Hf—3.0 at % Nd—0.1 at % Ni—0.5 at % Ge | ⊙ | ⊙ | ⊙ | ⊙ | ⊙ | ⊙ |
| 113 | Al—0.5 at % Hf—3.0 at % La—0.1 at % Ni—0.5 at % Ge | ⊙ | ⊙ | ⊙ | ⊙ | ⊙ | ⊙ |
| 114 | Al—0.5 at % Cr—3.0 at % Nd—0.1 at % Ni—0.5 at % Ge | ⊙ | ⊙ | ⊙ | ⊙ | ⊙ | ⊙ |
| 115 | Al—0.5 at % Cr—3.0 at % La—0.1 at % Ni—0.5 at % Ge | ⊙ | ⊙ | ⊙ | ⊙ | ⊙ | ⊙ |
| 116 | Al—0.5 at % Pt—3.0 at % Nd—0.1 at % Ni—0.5 at % Ge | ⊙ | ⊙ | ⊙ | ⊙ | ⊙ | ⊙ |
| 117 | Al—0.5 at % Pt—3.0 at % La—0.1 at % Ni—0.5 at % Ge | ⊙ | ⊙ | ⊙ | ⊙ | ⊙ | ⊙ |

TABLE 6

| | | Precipitate | | Precipitate | | | | | |
|---|---|---|---|---|---|---|---|---|---|
| | Composition of Al alloy film | size | | density | | Heat resistance | | | |
| No. | (balance: Al and incidental impurities) | 550° C. | 600° C. | 550° C. | 600° C. | 350° C. | 450° C. | 550° C. | 600° C. |
| 1 | Al | XXX | XXX | XXX | XXX | X | X | X | X |
| 2 | Al—2 at % Ni | XXX | XXX | XXX | XXX | X | X | X | X |
| 3 | Al—2 at % Co | XXX | XXX | XXX | XXX | X | X | X | X |
| 4 | Al—0.3 at % Nd—2.0 at % Ni | XXX | XXX | XXX | XXX | ◯ | X | X | X |
| 5 | Al—0.3 at % La—2.0 at % Ni | XXX | XXX | XXX | XXX | ◯ | X | X | X |
| 6 | Al—3.0 at % Nd—2.0 at % Ni | XXX | XXX | XXX | XXX | ⊙ | X | X | X |
| 7 | Al—3.0 at % La—2.0 at % Ni | XXX | XXX | XXX | XXX | ⊙ | X | X | X |
| 8 | Al—0.3 at % La—0.1 at % Ni | XXX | XXX | XXX | XXX | ◯ | X | X | X |
| 9 | Al—3.0 at % La—0.1 at % Ni | XXX | XXX | XXX | XXX | ⊙ | X | X | X |
| 10 | Al—0.3 at % La—0.1 at % Ni—0.5 at % Ge | X⊙⊙ | X⊙⊙ | X⊙⊙ | X⊙⊙ | ◯ | X | X | X |
| 11 | Al—3.0 at % La—0.1 at % Ni—0.5 at % Ge | X⊙⊙ | X⊙⊙ | X⊙⊙ | X⊙⊙ | ⊙ | X | X | X |
| 12 | Al—0.3 at % La—0.1 at % Co—0.5 at % Ge | X⊙⊙ | X⊙⊙ | X⊙⊙ | X⊙⊙ | ◯ | X | X | X |
| 13 | Al—3.0 at % La—0.1 at % Co—0.5 at % Ge | X⊙⊙ | X⊙⊙ | X⊙⊙ | X⊙⊙ | ⊙ | X | X | X |
| 14 | Al—0.3 at % La—0.1 at % Ni—0.1 at % Ta | ⊙XX | ⊙XX | ◯XX | ◯XX | ⊙ | ⊙ | ◯ | ◯ |
| 15 | Al—3.0 at % La—0.1 at % Ni—0.1 at % Ta | ⊙XX | ⊙XX | ◯XX | ◯XX | ⊙ | ⊙ | ◯ | ◯ |
| 16 | Al—0.3 at % La—0.1 at % Ni—0.5 at % Ta | ⊙XX | ⊙XX | ⊙XX | ⊙XX | ⊙ | ⊙ | ⊙ | ⊙ |
| 17 | Al—3.0 at % La—0.1 at % Ni—0.5 at % Ta | ⊙XX | ⊙XX | ⊙XX | ⊙XX | ⊙ | ⊙ | ⊙ | ⊙ |
| 18 | Al—0.3 at % La—0.1 at % Co—0.5 at % Ta | ⊙XX | ⊙XX | ⊙XX | ⊙XX | ⊙ | ⊙ | ⊙ | ⊙ |
| 19 | Al—3.0 at % La—0.1 at % Co—0.5 at % Ta | ⊙XX | ⊙XX | ⊙XX | ⊙XX | ⊙ | ⊙ | ⊙ | ⊙ |
| 20 | Al—0.3 at % La—0.1 at % Ni—5.0 at % Ta | ⊙XX | ⊙XX | ⊙XX | ⊙XX | ⊙ | ⊙ | ⊙ | ⊙ |
| 21 | Al—0.3 at % La—0.1 at % Ni—5.0 at % Ta | ⊙XX | ⊙XX | ⊙XX | ⊙XX | ⊙ | ⊙ | ⊙ | ⊙ |
| 22 | Al—0.3 at % La—0.2 at % Ge—0.1 at % Ta | ⊙⊙X | ⊙⊙X | ◯◯X | ◯◯X | ⊙ | ⊙ | ◯ | ◯ |
| 23 | Al—3.0 at % La—0.2 at % Ge—0.1 at % Ta | ⊙⊙X | ⊙⊙X | ◯◯X | ◯◯X | ⊙ | ⊙ | ◯ | ◯ |
| 24 | Al—0.3 at % La—0.2 at % Ge—0.5 at % Ta | ⊙⊙X | ⊙⊙X | ⊙⊙X | ⊙⊙X | ⊙ | ⊙ | ⊙ | ⊙ |
| 25 | Al—3.0 at % La—0.2 at % Ge—0.5 at % Ta | ⊙⊙X | ⊙⊙X | ⊙⊙X | ⊙⊙X | ⊙ | ⊙ | ⊙ | ⊙ |
| 26 | Al—0.3 at % La—0.2 at % Ge—5.0 at % Ta | ⊙⊙X | ⊙⊙X | ⊙⊙X | ⊙⊙X | ⊙ | ⊙ | ⊙ | ⊙ |
| 27 | Al—3.0 at % La—0.2 at % Ge—5.0 at % Ta | ⊙⊙X | ⊙⊙X | ⊙⊙X | ⊙⊙X | ⊙ | ⊙ | ⊙ | ⊙ |
| 28 | Al—0.3 at % La—0.5 at % Ge—0.1 at % Ta | ⊙⊙X | ⊙⊙X | ◯◯X | ◯◯X | ⊙ | ⊙ | ◯ | ◯ |
| 29 | Al—3.0 at % La—0.5 at % Ge—0.1 at % Ta | ⊙⊙X | ⊙⊙X | ◯◯X | ◯◯X | ⊙ | ⊙ | ◯ | ◯ |
| 30 | Al—0.3 at % La—0.5 at % Ge—0.25 at % Ta | ⊙⊙X | ⊙⊙X | ⊙⊙X | ⊙⊙X | ⊙ | ⊙ | ⊙ | ◯ |
| 31 | Al—3.0 at % La—0.5 at % Ge—0.25 at % Ta | ⊙⊙X | ⊙⊙X | ⊙⊙X | ⊙⊙X | ⊙ | ⊙ | ⊙ | ◯ |
| 32 | Al—0.3 at % La—0.5 at % Ge—0.5 at % Ta | ⊙⊙X | ⊙⊙X | ⊙⊙X | ⊙⊙X | ⊙ | ⊙ | ⊙ | ⊙ |
| 33 | Al—0.6 at % La—0.5 at % Ge—0.5 at % Ta | ⊙⊙X | ⊙⊙X | ⊙⊙X | ⊙⊙X | ⊙ | ⊙ | ⊙ | ⊙ |
| 34 | Al—2.0 at % La—0.5 at % Ge—0.5 at % Ta | ⊙⊙X | ⊙⊙X | ⊙⊙X | ⊙⊙X | ⊙ | ⊙ | ⊙ | ⊙ |
| 35 | Al—2.0 at % Nd—0.5 at % Ge—0.5 at % Ta | ⊙⊙X | ⊙⊙X | ⊙⊙X | ⊙⊙X | ⊙ | ⊙ | ⊙ | ⊙ |

| | | | | | Contact | Resistance | Resistance to |
|---|---|---|---|---|---|---|---|
| | | | | | resistance | to stripping | organic alkaline |
| | Composition of Al alloy film | Wiring resistance | | | with ITO | solution | developer |
| No. | (balance: Al and incidental impurities) | 450° C. | 550° C. | 600° C. | 600° C. | 600° C. | — |
| 1 | Al | ⊙ | ⊙ | ⊙ | X | ⊙ | ⊙ |
| 2 | Al—2 at % Ni | ⊙ | ⊙ | ⊙ | ⊙ | X | X |
| 3 | Al—2 at % Co | ⊙ | ⊙ | ⊙ | ⊙ | X | X |
| 4 | Al—0.3 at % Nd—2.0 at % Ni | ⊙ | ⊙ | ⊙ | ⊙ | Δ | Δ |
| 5 | Al—0.3 at % La—2.0 at % Ni | ⊙ | ⊙ | ⊙ | ⊙ | Δ | Δ |
| 6 | Al—3.0 at % Nd—2.0 at % Ni | ⊙ | ⊙ | ⊙ | ⊙ | Δ | ◯ |
| 7 | Al—3.0 at % La—2.0 at % Ni | ⊙ | ⊙ | ⊙ | ⊙ | Δ | ◯ |
| 8 | Al—0.3 at % La—0.1 at % Ni | ⊙ | ⊙ | ⊙ | X | Δ | ⊙ |
| 9 | Al—3.0 at % La—0.1 at % Ni | ⊙ | ⊙ | ⊙ | X | Δ | ⊙ |
| 10 | Al—0.3 at % La—0.1 at % Ni—0.5 at % Ge | ⊙ | ⊙ | ⊙ | ⊙ | ◯ | ⊙ |
| 11 | Al—3.0 at % La—0.1 at % Ni—0.5 at % Ge | ⊙ | ⊙ | ⊙ | ⊙ | ◯ | ⊙ |
| 12 | Al—0.3 at % La—0.1 at % Co—0.5 at % Ge | ⊙ | ⊙ | ⊙ | ⊙ | ◯ | ⊙ |
| 13 | Al—3.0 at % La—0.1 at % Co—0.5 at % Ge | ⊙ | ⊙ | ⊙ | ⊙ | ◯ | ⊙ |
| 14 | Al—0.3 at % La—0.1 at % Ni—0.1 at % Ta | ⊙ | ⊙ | ⊙ | X | ⊙ | ⊙ |
| 15 | Al—3.0 at % La—0.1 at % Ni—0.1 at % Ta | ⊙ | ⊙ | ⊙ | X | ⊙ | ⊙ |
| 16 | Al—0.3 at % La—0.1 at % Ni—0.5 at % Ta | ◯ | ⊙ | ⊙ | X | ⊙ | ⊙ |
| 17 | Al—3.0 at % La—0.1 at % Ni—0.5 at % Ta | ◯ | ⊙ | ⊙ | X | ⊙ | ⊙ |
| 18 | Al—0.3 at % La—0.1 at % Co—0.5 at % Ta | ◯ | ⊙ | ⊙ | X | ⊙ | ⊙ |
| 19 | Al—3.0 at % La—0.1 at % Co—0.5 at % Ta | ◯ | ⊙ | ⊙ | X | ⊙ | ⊙ |
| 20 | Al—0.3 at % La—0.1 at % Ni—5.0 at % Ta | ◯ | ◯ | ◯ | X | ⊙ | ⊙ |
| 21 | Al—0.3 at % La—0.1 at % Ni—5.0 at % Ta | ◯ | ◯ | ◯ | X | ⊙ | ⊙ |
| 22 | Al—0.3 at % La—0.2 at % Ge—0.1 at % Ta | ⊙ | ⊙ | ⊙ | X | ⊙ | ⊙ |
| 23 | Al—3.0 at % La—0.2 at % Ge—0.1 at % Ta | ⊙ | ⊙ | ⊙ | X | ⊙ | ⊙ |
| 24 | Al—0.3 at % La—0.2 at % Ge—0.5 at % Ta | ⊙ | ⊙ | ⊙ | X | ⊙ | ⊙ |
| 25 | Al—3.0 at % La—0.2 at % Ge—0.5 at % Ta | ⊙ | ⊙ | ⊙ | X | ⊙ | ⊙ |
| 26 | Al—0.3 at % La—0.2 at % Ge—5.0 at % Ta | ◯ | ◯ | ◯ | X | ⊙ | ⊙ |
| 27 | Al—3.0 at % La—0.2 at % Ge—5.0 at % Ta | ◯ | ◯ | ◯ | X | ⊙ | ⊙ |
| 28 | Al—0.3 at % La—0.5 at % Ge—0.1 at % Ta | ⊙ | ⊙ | ⊙ | X | ⊙ | ⊙ |
| 29 | Al—3.0 at % La—0.5 at % Ge—0.1 at % Ta | ⊙ | ⊙ | ⊙ | X | ⊙ | ⊙ |
| 30 | Al—0.3 at % La—0.5 at % Ge—0.25 at % Ta | ⊙ | ⊙ | ⊙ | X | ⊙ | ⊙ |
| 31 | Al—3.0 at % La—0.5 at % Ge—0.25 at % Ta | ⊙ | ⊙ | ⊙ | X | ⊙ | ⊙ |
| 32 | Al—0.3 at % La—0.5 at % Ge—0.5 at % Ta | ⊙ | ⊙ | ⊙ | X | ⊙ | ⊙ |
| 33 | Al—0.6 at % La—0.5 at % Ge—0.5 at % Ta | ⊙ | ⊙ | ⊙ | X | ⊙ | ⊙ |
| 34 | Al—2.0 at % La—0.5 at % Ge—0.5 at % Ta | ⊙ | ⊙ | ⊙ | X | ⊙ | ⊙ |
| 35 | Al—2.0 at % Nd—0.5 at % Ge—0.5 at % Ta | ⊙ | ⊙ | ⊙ | X | ⊙ | ⊙ |

TABLE 7

| | | Precipitate | | Precipitate | | | | | |
|---|---|---|---|---|---|---|---|---|---|
| | Composition of Al alloy film | size | | density | | Heat resistance | | | |
| No. | (balance: Al and incidental impurities) | 550° C. | 600° C. | 550° C. | 600° C. | 350° C. | 450° C. | 550° C. | 600° C. |
| 36 | Al—2.0 at % Gd—0.5 at % Ge—0.5 at % Ta | ⊙⊙X | ⊙⊙X | ⊙⊙X | ⊙⊙X | ⊙ | ⊙ | ⊙ | ⊙ |
| 37 | Al—2.0 at % Y—0.5 at % Ge—0.5 at % Ta | ⊙⊙X | ⊙⊙X | ⊙⊙X | ⊙⊙X | ⊙ | ⊙ | ⊙ | ⊙ |
| 38 | Al—2.0 at % Sc—0.5 at % Ge—0.5 at % Ta | ⊙⊙X | ⊙⊙X | ⊙⊙X | ⊙⊙X | ⊙ | ⊙ | ⊙ | ⊙ |
| 39 | Al—2.0 at % Ce—0.5 at % Ge—0.5 at % Ta | ⊙⊙X | ⊙⊙X | ⊙⊙X | ⊙⊙X | ⊙ | ⊙ | ⊙ | ⊙ |
| 40 | Al—2.0 at % Dy—0.5 at % Ge—0.5 at % Ta | ⊙⊙X | ⊙⊙X | ⊙⊙X | ⊙⊙X | ⊙ | ⊙ | ⊙ | ⊙ |
| 41 | Al—3.0 at % La—0.5 at % Ge—0.5 at % Ta | ⊙⊙X | ⊙⊙X | ⊙⊙X | ⊙⊙X | ⊙ | ⊙ | ⊙ | ⊙ |
| 42 | Al—0.3 at % La—0.5 at % Ge—1.5 at % Ta | ⊙⊙X | ⊙⊙X | ⊙⊙X | ⊙⊙X | ⊙ | ⊙ | ⊙ | ⊙ |
| 43 | Al—3.0 at % La—0.5 at % Ge—1.5 at % Ta | ⊙⊙X | ⊙⊙X | ⊙⊙X | ⊙⊙X | ⊙ | ⊙ | ⊙ | ⊙ |
| 44 | Al—0.3 at % La—0.5 at % Ge—5.0 at % Ta | ⊙⊙X | ⊙⊙X | ⊙⊙X | ⊙⊙X | ⊙ | ⊙ | ⊙ | ⊙ |
| 45 | Al—3.0 at % La—0.5 at % Ge—5.0 at % Ta | ⊙⊙X | ⊙⊙X | ⊙⊙X | ⊙⊙X | ⊙ | ⊙ | ⊙ | ⊙ |
| 46 | Al—0.3 at % La—0.5 at % Cu—0.1 at % Ta | ⊙⊙X | ⊙⊙X | ◯◯X | ◯◯X | ⊙ | ⊙ | ◯ | ◯ |
| 47 | Al—3.0 at % La—0.5 at % Cu—0.1 at % Ta | ⊙⊙X | ⊙⊙X | ◯◯X | ◯◯X | ⊙ | ⊙ | ◯ | ◯ |
| 48 | Al—0.3 at % La—0.5 at % Cu—0.5 at % Ta | ⊙⊙X | ⊙⊙X | ⊙⊙X | ⊙⊙X | ⊙ | ⊙ | ⊙ | ⊙ |
| 49 | Al—3.0 at % La—0.5 at % Cu—0.5 at % Ta | ⊙⊙X | ⊙⊙X | ⊙⊙X | ⊙⊙X | ⊙ | ⊙ | ⊙ | ⊙ |
| 50 | Al—0.3 at % La—0.5 at % Cu—5.0 at % Ta | ⊙⊙X | ⊙⊙X | ⊙⊙X | ⊙⊙X | ⊙ | ⊙ | ⊙ | ⊙ |
| 51 | Al—3.0 at % La—0.5 at % Cu—5.0 at % Ta | ⊙⊙X | ⊙⊙X | ⊙⊙X | ⊙⊙X | ⊙ | ⊙ | ⊙ | ⊙ |
| 52 | Al—0.3 at % La—2.0 at % Ge—0.1 at % Ta | ⊙⊙X | ⊙⊙X | ◯◯X | ◯◯X | ⊙ | ⊙ | ◯ | ◯ |
| 53 | Al—3.0 at % La—2.0 at % Ge—0.1 at % Ta | ⊙⊙X | ⊙⊙X | ◯◯X | ◯◯X | ⊙ | ⊙ | ◯ | ◯ |
| 54 | Al—0.3 at % La—2.0 at % Ge—0.5 at % Ta | ⊙⊙X | ⊙⊙X | ⊙⊙X | ⊙⊙X | ⊙ | ⊙ | ⊙ | ⊙ |
| 55 | Al—3.0 at % La—2.0 at % Ge—0.5 at % Ta | ⊙⊙X | ⊙⊙X | ⊙⊙X | ⊙⊙X | ⊙ | ⊙ | ⊙ | ⊙ |
| 56 | Al—0.3 at % La—0.5 at % Ta | ⊙XX | ⊙XX | ⊙XX | ⊙XX | ⊙ | ⊙ | ◯ | ◯ |
| 57 | Al—0.3 at % La—5.0 at % Ta | ⊙XX | ⊙XX | ⊙XX | ⊙XX | ⊙ | ⊙ | ◯ | ◯ |
| 58 | Al—0.3 at % Nd—0.1 at % Ta | ⊙XX | ⊙XX | ◯XX | ◯XX | ⊙ | ⊙ | ◯ | ◯ |
| 59 | Al—0.3 at % Nd—0.5 at % Ta | ⊙XX | ⊙XX | ⊙XX | ⊙XX | ⊙ | ⊙ | ◯ | ◯ |
| 60 | Al—0.3 at % Nd—5.0 at % Ta | ⊙XX | ⊙XX | ⊙XX | ⊙XX | ⊙ | ⊙ | ◯ | ◯ |
| 61 | Al—2.0 at % La—0.5 at % Ta | ⊙XX | ⊙XX | ⊙XX | ⊙XX | ⊙ | ⊙ | ◯ | ◯ |
| 62 | Al—2.0 at % La—5.0 at % Ta | ⊙XX | ⊙XX | ⊙XX | ⊙XX | ⊙ | ⊙ | ⊙ | ◯ |
| 63 | Al—2.0 at % Nd—0.1 at % Ta | ⊙XX | ⊙XX | ◯XX | ◯XX | ⊙ | ⊙ | ◯ | ◯ |
| 64 | Al—2.0 at % Nd—0.5 at % Ta | ⊙XX | ⊙XX | ⊙XX | ⊙XX | ⊙ | ⊙ | ◯ | ◯ |
| 65 | Al—2.0 at % Nd—5.0 at % Ta | ⊙XX | ⊙XX | ⊙XX | ⊙XX | ⊙ | ⊙ | ⊙ | ◯ |
| 66 | Al—3.0 at % La—0.5 at % Ta | ⊙XX | ⊙XX | ⊙XX | ⊙XX | ⊙ | ⊙ | ◯ | ◯ |
| 67 | Al—3.0 at % La—5.0 at % Ta | ⊙XX | ⊙XX | ⊙XX | ⊙XX | ⊙ | ⊙ | ⊙ | ◯ |
| 68 | Al—3.0 at % Nd—0.5 at % Ta | ⊙XX | ⊙XX | ⊙XX | ⊙XX | ⊙ | ⊙ | ◯ | ◯ |
| 69 | Al—3.0 at % Nd—5.0 at % Ta | ⊙XX | ⊙XX | ⊙XX | ⊙XX | ⊙ | ⊙ | ⊙ | ◯ |

| | | | | | Contact | Resistance | Resistance to |
|---|---|---|---|---|---|---|---|
| | | | | | resistance | to stripping | organic alkaline |
| | Composition of Al alloy film | Wiring resistance | | | with ITO | solution | developer |
| No. | (balance: Al and incidental impurities) | 450° C. | 550° C. | 600° C. | 600° C. | 600° C. | — |
| 36 | Al—2.0 at % Gd—0.5 at % Ge—0.5 at % Ta | ⊙ | ⊙ | ⊙ | X | ⊙ | ⊙ |
| 37 | Al—2.0 at % Y—0.5 at % Ge—0.5 at % Ta | ⊙ | ⊙ | ⊙ | X | ⊙ | ⊙ |
| 38 | Al—2.0 at % Sc—0.5 at % Ge—0.5 at % Ta | ⊙ | ⊙ | ⊙ | X | ⊙ | ⊙ |
| 39 | Al—2.0 at % Ce—0.5 at % Ge—0.5 at % Ta | ⊙ | ⊙ | ⊙ | X | ⊙ | ⊙ |
| 40 | Al—2.0 at % Dy—0.5 at % Ge—0.5 at % Ta | ⊙ | ⊙ | ⊙ | X | ⊙ | ⊙ |
| 41 | Al—3.0 at % La—0.5 at % Ge—0.5 at % Ta | ⊙ | ⊙ | ⊙ | X | ⊙ | ⊙ |
| 42 | Al—0.3 at % La—0.5 at % Ge—1.5 at % Ta | ◯ | ⊙ | ⊙ | X | ⊙ | ⊙ |
| 43 | Al—3.0 at % La—0.5 at % Ge—1.5 at % Ta | ◯ | ⊙ | ⊙ | X | ⊙ | ⊙ |
| 44 | Al—0.3 at % La—0.5 at % Ge—5.0 at % Ta | ◯ | ◯ | ◯ | X | ⊙ | ⊙ |
| 45 | Al—3.0 at % La—0.5 at % Ge—5.0 at % Ta | ◯ | ◯ | ◯ | X | ⊙ | ⊙ |
| 46 | Al—0.3 at % La—0.5 at % Cu—0.1 at % Ta | ⊙ | ⊙ | ⊙ | X | ⊙ | ⊙ |
| 47 | Al—3.0 at % La—0.5 at % Cu—0.1 at % Ta | ⊙ | ⊙ | ⊙ | X | ⊙ | ⊙ |
| 48 | Al—0.3 at % La—0.5 at % Cu—0.5 at % Ta | ⊙ | ⊙ | ⊙ | X | ⊙ | ⊙ |
| 49 | Al—3.0 at % La—0.5 at % Cu—0.5 at % Ta | ⊙ | ⊙ | ⊙ | X | ⊙ | ⊙ |
| 50 | Al—0.3 at % La—0.5 at % Cu—5.0 at % Ta | ◯ | ◯ | ◯ | X | ⊙ | ⊙ |
| 51 | Al—3.0 at % La—0.5 at % Cu—5.0 at % Ta | ◯ | ◯ | ◯ | X | ⊙ | ⊙ |
| 52 | Al—0.3 at % La—2.0 at % Ge—0.1 at % Ta | ⊙ | ⊙ | ⊙ | X | ⊙ | ⊙ |
| 53 | Al—3.0 at % La—2.0 at % Ge—0.1 at % Ta | ⊙ | ⊙ | ⊙ | X | ⊙ | ⊙ |
| 54 | Al—0.3 at % La—2.0 at % Ge—0.5 at % Ta | ⊙ | ⊙ | ⊙ | X | ⊙ | ⊙ |
| 55 | Al—3.0 at % La—2.0 at % Ge—0.5 at % Ta | ⊙ | ⊙ | ⊙ | X | ⊙ | ⊙ |
| 56 | Al—0.3 at % La—0.5 at % Ta | ◯ | ⊙ | ⊙ | X | ⊙ | ⊙ |
| 57 | Al—0.3 at % La—5.0 at % Ta | ◯ | ◯ | ◯ | X | ⊙ | ⊙ |
| 58 | Al—0.3 at % Nd—0.1 at % Ta | ⊙ | ⊙ | ⊙ | X | ⊙ | ⊙ |
| 59 | Al—0.3 at % Nd—0.5 at % Ta | ◯ | ⊙ | ⊙ | X | ⊙ | ⊙ |
| 60 | Al—0.3 at % Nd—5.0 at % Ta | ◯ | ◯ | ◯ | X | ⊙ | ⊙ |
| 61 | Al—2.0 at % La—0.5 at % Ta | ◯ | ⊙ | ⊙ | X | ⊙ | ⊙ |
| 62 | Al—2.0 at % La—5.0 at % Ta | ◯ | ◯ | ◯ | X | ⊙ | ⊙ |
| 63 | Al—2.0 at % Nd—0.1 at % Ta | ⊙ | ⊙ | ⊙ | X | ⊙ | ⊙ |
| 64 | Al—2.0 at % Nd—0.5 at % Ta | ◯ | ⊙ | ⊙ | X | ⊙ | ⊙ |
| 65 | Al—2.0 at % Nd—5.0 at % Ta | ◯ | ◯ | ◯ | X | ⊙ | ⊙ |
| 66 | Al—3.0 at % La—0.5 at % Ta | ◯ | ⊙ | ⊙ | X | ⊙ | ⊙ |
| 67 | Al—3.0 at % La—5.0 at % Ta | ◯ | ◯ | ◯ | X | ⊙ | ⊙ |
| 68 | Al—3.0 at % Nd—0.5 at % Ta | ◯ | ⊙ | ⊙ | X | ⊙ | ⊙ |
| 69 | Al—3.0 at % Nd—5.0 at % Ta | ◯ | ◯ | ◯ | X | ⊙ | ⊙ |

TABLE 8

| Item | | ⊙ | ◯ | Δ | X |
|---|---|---|---|---|---|
| Precipitate size | First | 20 nm to 800 nm | more than 800 nm and 1 μm or less | more than 1 μm | no precipitate |
| (diameter, nm) | precipitate | | | | or |
| | | | | | less than 20 nm |
| | Second | 200 nm to 800 nm | more than 800 nm and 1 μm or less | more than 1 μm | no precipitate |
| | precipitate | | | | or |
| | | | | | less than 200 nm |
| | Third | 200 nm to 2 μm | more than 2 μm and 3 μm or less | more than 3 μm | no precipitate |
| | precipitate | | | | or |
| | | | | | less than 200 nm |
| Precipitate density | First | 2,000,000 or more | 500,000 or more and less than | 200,500 or more and less than 500,000 | less than 200,500 |
| (particles/mm²)* | precipitate | | 2,000,000 | | |
| | Second | 25,000 or more | 10,000 or more and less than | 5,000 or more and less than 10,000 | less than 5,000 |
| | precipitate | | 25,000 | | |
| | Third | 5,000 or more | 2,000 or more and less than 5,000 | 1,000 or more and less than 2,000 | less than 1,000 |
| | precipitate | | | | |
| Heat resistance (hillock | | 1 × 10⁸ or less | more than 1 × 10⁸ and 5 × 10⁸ or | more than 5 × 10⁸ and 1 × 10⁹ or less | 1 × 10⁹ or more |
| density, particles/m²) | | | less | | |
| Wiring resistance | 450° C. | 8 or less | more than 8 and 15 or less | more than 15 and less than 20 | 20 or more |
| (μΩcm) | 550° C. | 7 or less | more than 7 and 10 or less | more than 10 and less than 12 | 12 or more |
| | 600° C. | 5 or less | more than 5 and 8 or less | more than 8 and less than 10 | 10 or more |

| | | | | |
|---|---|---|---|---|
| Contact resistance with ITO | 100 or less | more than 100 and 200 or less | more than 200 and less than 1000 | 1000 or more |
| (Ω/100 μm²) | | | | |
| Resistance to stripping | 0.1 or less | more than 0.1 and 1 or less | more than 1 and less than 5 | 5 or more |
| solution (number of corrosion | | | | |
| marks, numbers/100 μm²) | | | | |
| Resistance to organic alkaline | 20 or less | more than 20 and 30 or less | more than 30 and less than 40 | 40 or more |
| developer (etch rate, nm/min) | | | | |

Tables 1 to 5 will now be discussed. In each of these tables, “⊙” in the column of “Precipitate size (550° C./600° C.)” indicates that the size of each of the first to third precipitates satisfies the corresponding requirement represented by “⊙” (the same is true for “◯” and “Δ”). Furthermore, “⊙” in the column of “Precipitate density (550° C./600° C.)” indicates that the density of each of the first and second precipitates satisfies the corresponding requirement represented by “⊙” (the same is true for “◯” and “Δ”). That is, “⊙” in the columns of “Precipitate size (550° C./600° C.)” and “Precipitate density (550° C./600° C.)” indicates that the size and density of each of the first to third precipitates satisfy the respective requirements represented by “⊙”. Similarly, “◯” in the columns of “Precipitate size (550° C./600° C.)” and “Precipitate density (550° C./600° C.)” indicates that the size and density of each of the first to third precipitates satisfy the respective requirements represented by “◯”.

Each of the Al alloy films described in Tables 1 to 5 corresponds to the third Al alloy film according to the present invention and satisfies the alloy composition specified in the present invention and the requirements (size and density) of the first to third precipitates, thereby resulting in excellent heat resistance not only at a low temperature (350° C.) but also at a high temperature of 450° C. to 600° C. With respect to the electrical resistance after the high-temperature heat treatment, each Al alloy film has a lower electrical resistance than a refractory metal. Each Al alloy film has satisfactory resistance to the alkaline developer and the stripping solution after the high-temperature heat treatment. Furthermore, it was possible to greatly reduce the direct contact resistance between the Al alloy film and ITO (transparent pixel electrode).

For example, in No. 43 in Table 2, results of the heat treatment of the Al-0.5 atomic percent Ta-2.0 atomic percent La-0.1 atomic percent Ni-0.5 atomic percent Ge alloy film are described. The following precipitates were obtained when the alloy film was treated at a temperature of 550° C. or 600° C.

The first precipitates (Al—Ta—La-containing precipitates) having a size (equivalent circle diameter) of ⊙ (20 nm to 800 nm) are present at a density (particles/mm²) of ⊙ (2,000,000 particles/mm² or more).

The second precipitates (Al—Ge—La-containing precipitates) having a size (equivalent circle diameter) of 0 (200 nm to 800 nm) are present at a density (particles/mm²) of ⊙ (25,000 particles/mm² or more).

The third precipitates (Al—Ni—Ge—La-containing precipitates) having a size (equivalent circle diameter) of ⊙ (200 nm to 800 nm) are present at a density (particles/mm²) of ⊙ (5,000 particles/mm² or more).

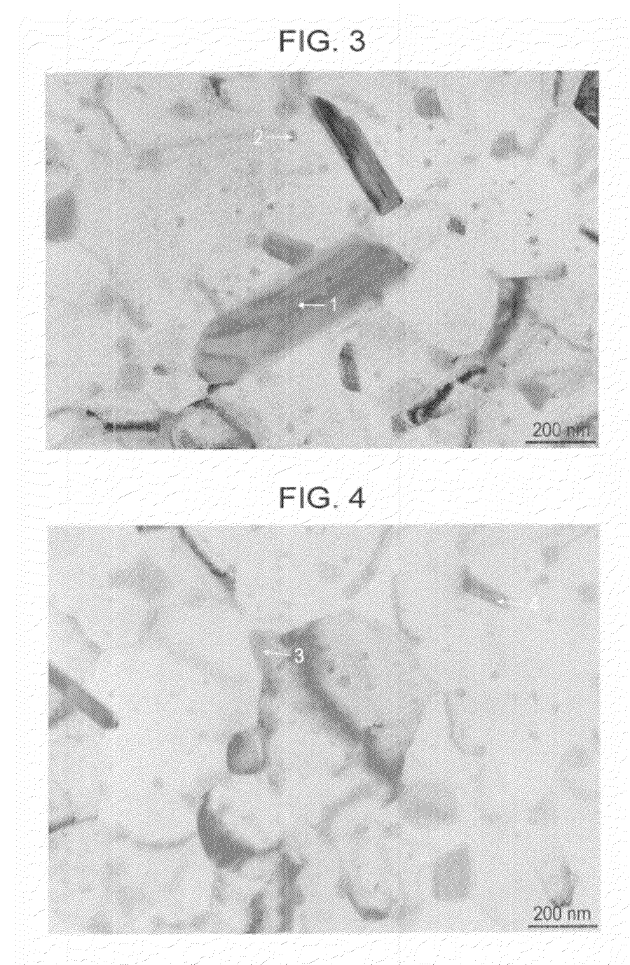

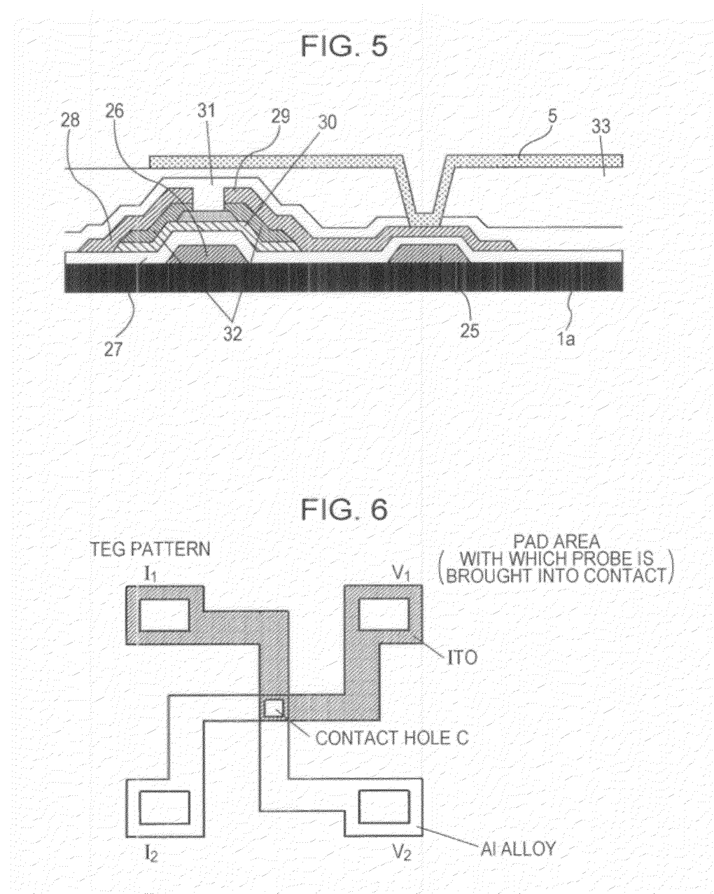

For the purpose of reference, compositions of precipitates (1 to 4) present in No. 43 of Table 2 were analyzed by EDX using a semiquantitative method. Table 9 illustrates the results. As described below, the precipitates (1 to 4) indicate precipitates observed in FIGS. 3 and 4.

TABLE 9

| Precipitate | Al | Ni | Ge | La | Ta |
|---|---|---|---|---|---|
| 1 | 50.6 | 15.7 | 19.4 | 14.1 | 0.2 |
| 2 | 95.0 | — | — | 1.5 | 3.5 |
| 3 | 90.5 | — | — | 2.7 | 6.8 |
| 4 | 30.5 | — | 44.3 | 25.2 | — |

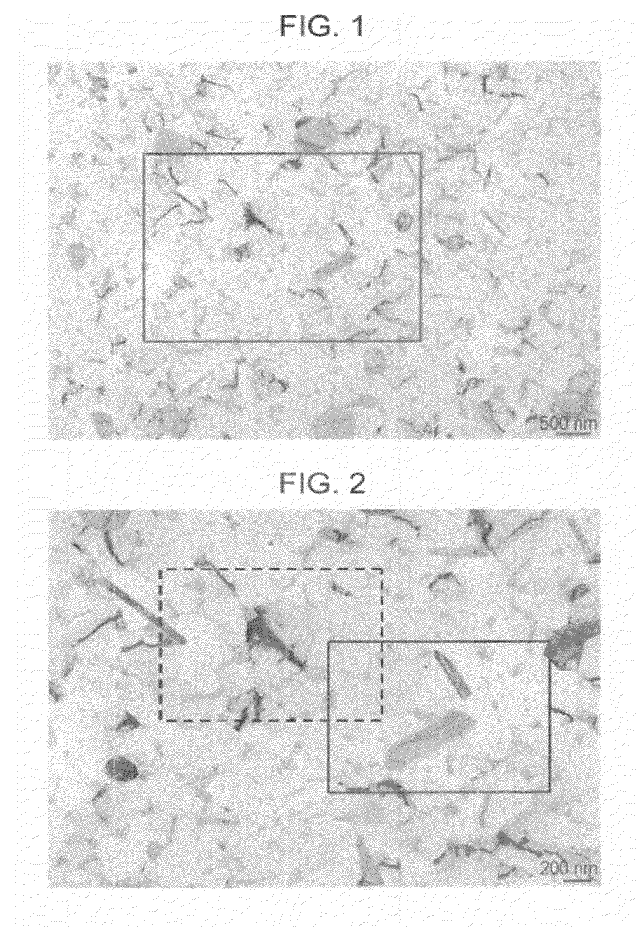

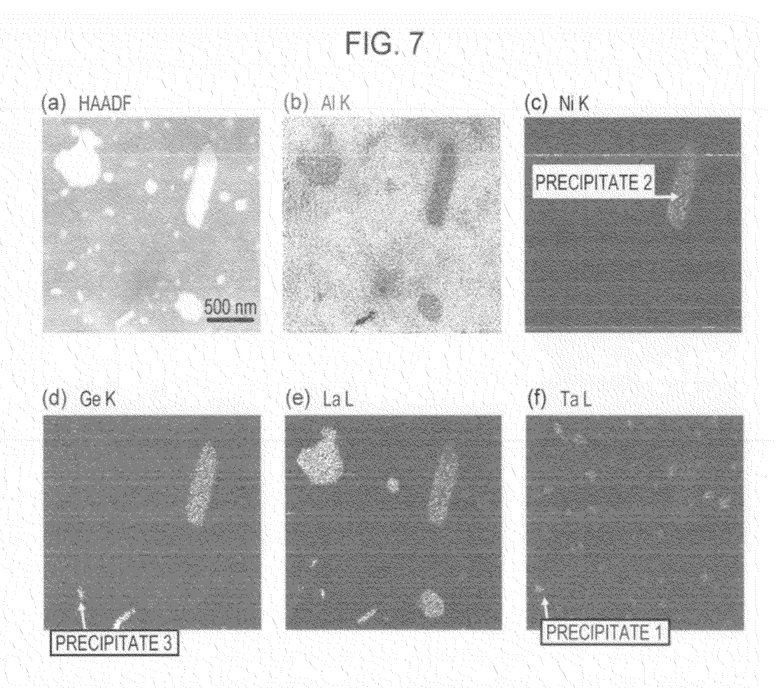

To elucidate the shape and distribution state of these precipitates (1 to 4), planar transmission electron microscope (TEM) micrographs of the Al alloy film of No. 43 (thickness: 300 nm) after heat treatment is performed at 600° C. for 10 minutes are illustrated in FIG. 1, FIG. 2 which is an enlarged view of FIG. 1, and FIGS. 3 and 4 which are enlarged views of FIG. 2. Precipitates 1 and 2 are illustrated in FIG. 3. Precipitates 3 and 4 are illustrated in FIG. 4. These precipitates have various sizes and are widely distributed in the Al alloy film. For this reason, the micrographs taken with different magnifications are illustrated. FIG. 2 (magnification: ×60,000) is an enlarged view of FIG. 1 (magnification: ×30,000). FIGS. 3 and 4 (magnification: ×150,000) are enlarged views of FIG. 2. FIGS. 7(a) to 7(f) are surface analysis photographs by EDX of the precipitates illustrated in FIGS. 3 and 4 (FIG. 3: precipitate 1 and precipitate 2; and FIG. 4: precipitate 3).

Next, Tables 6 and 7 will be discussed. In each of Tables 6 and 7, “xxx” in the columns of “Precipitate size (550° C./600° C.)” and “Precipitate density (550° C./600° C.)” (see Nos. 1 to 9 in Table 6) indicates that both of the size and density of each of the first precipitates, the second precipitates, and the third precipitates satisfy the respective requirements represented by “x”.

In each of Tables 6 and 7, “x⊙⊙” in the columns of “Precipitate size (550° C./600° C.)” and “Precipitate density (550° C./600° C.)” (see Nos. 10 to 13 in Table 6) indicates that both of the size and density of the first precipitates satisfy the respective requirements represented by “x” and that both of the size and density of each of the second precipitates and the third precipitates satisfy the respective requirements represented by “⊙”.

In each of Tables 6 and 7, “⊙xx” in the columns of “Precipitate size (550° C./600° C.)” and “Precipitate density (550° C./600° C.)” (see Nos. 16 to 21, 56, 57, 59 to 62, and 64 to 69 in Table 6) indicates that both of the size and density of the first precipitates satisfy the respective requirements represented by “⊙” and that both of the size and density of each of the second precipitates and the third precipitates satisfy the respective requirements represented by “x”. In each of Tables 6 and 7, “⊙xx” in the column of “Precipitate size (550° C./600° C.)” and “◯xx” in the column of “Precipitate density (550° C./600° C.)” (see Nos. 14, 15, 58, and 63 in Tables 6 and 7) indicate that the size of the first precipitates satisfies the requirement represented by “⊙”, the density of the first precipitates satisfies the requirement represented by “◯”, and that both of the size and density of each of the second precipitates and the third precipitates satisfy the respective requirements represented by “x”.

In each of Tables 6 and 7, “⊙⊙x” in the columns of “Precipitate size (550° C./600° C.)” and “Precipitate density (550° C./600° C.)” (see Nos. 24 to 27, 30 to 45, 48 to 51, 54, and 55 in Tables 6 and 7) indicates that both of the size and density of each of the first precipitates and the second precipitates satisfy the respective requirements represented by “⊙” and that both of the size and density of the third precipitates satisfy the respective requirements represented by “x”. In each of Tables 6 and 7, “⊙⊙x” in the column of “Precipitate size (550° C./600° C.)” and “◯xx” in the column of “Precipitate density (550° C./600° C.)” (see Nos. 22, 23, 28, 29, 46, 47, 52, and 53 in Tables 6 and 7) indicate that the size of each of the first precipitates and the second precipitates satisfies the requirement represented by “⊙”, the density of each of the first precipitates and the second precipitates satisfies the requirement represented by “◯”, and that both of the size and density of the third precipitates satisfy the respective requirements represented by “x”.

Each of the Al alloy films of Nos. 14 to 21 and 56 to 69 described in Tables 6 and 7 corresponds to the first Al alloy film according to the present invention and satisfies the alloy composition specified in the present invention (strictly speaking, Nos. 14 to 21 each contain Ni or Co in addition to the group X element and the rare-earth element) and the requirements (size and density) of the first precipitates, thereby resulting in excellent heat resistance in a wide temperature range from low temperatures (350° C.) to high temperatures (450° C. to 600° C.). Furthermore, they also have low electrical resistance after the high-temperature heat treatment, high resistance to the stripping solution, and excellent resistance to the alkaline developer. However, these Al alloy films do not contain Cu and/or Ge. Thus, the films do not satisfy the requirements (size and density) of the second precipitates and the third precipitates. This resulted in a reduction in resistance to the stripping solution and an increase in contact resistance with ITO.

Each of the Al alloy films of Nos. 22 to 55 described in Tables 6 and 7 corresponds to the second Al alloy film according to the present invention and satisfies the alloy composition specified in the present invention (strictly speaking, they each contain Ge or Cu in addition to the group X element and the rare-earth element) and the requirements (size and density) of the first precipitates, thereby resulting in excellent heat resistance in a wide temperature range from low temperatures (350° C.) to high temperatures (450° C. to 600° C.). Furthermore, they also have low electrical resistance after the high-temperature heat treatment, high resistance to the stripping solution, and excellent resistance to the alkaline developer. However, these Al alloy films do not contain Ni and/or Co. Thus, the films do not satisfy the requirements (size and density) of the third precipitates. This resulted in a reduction in resistance to the stripping solution and an increase in contact resistance with ITO.

In contrast, Nos. 1 to 13 described in Table 6 do not satisfy the alloy composition specified in the present invention or the requirements (size and density) of the first, second, or third precipitates. Thus, they have disadvantages described below.

In No. 1 in Table 6, the film was composed of pure Al, which serves as a conventional example. A desired precipitate was not formed, thus reducing the heat resistance.

No. 2 or 3 in Table 6 contained Ni or Co and did not contain the group X element or the rare-earth element, which serves as a comparative example. None of the desired first, second, and third precipitates were formed, thus reducing the heat resistance.

Nos. 4 to 9 in Table 6 each contained Ni and the rare-earth element and did not contain the group X element, which serve as a comparative example. None of the desired first, second, and third precipitates were formed, thus reducing the heat resistance. They each contained the rare-earth element and thus had satisfactory resistance to the alkaline developer. Nos. 4 to 7 each having a high Ni content of 2.0% had low contact resistance with ITO without Cu or Ge. In contrast, Nos. 8 and 9 (without adding Cu or Ge) each having a low Ni content of 0.1 atomic percent had high contact resistance with ITO.

Nos. 10 to 13 in Table 6 each contained Ni or Co, the rare-earth element, and Ge and did not contain the group X element, which serve as comparative examples. The desired first precipitates (size and density) were not formed, thus reducing the heat resistance. However, they contained the rare-earth element, and the desired second and third precipitates (size and density) were formed. Thus, they had satisfactory resistance to the alkaline developer. Furthermore, they contained both Ni and Cu, thus reducing the contact resistance with ITO.

While the present invention has been described in detail above with references to specific embodiments thereof, it will be apparent to one with skill in the art that various changes and modifications may be made without departing from the spirit and scope of the present invention.

This application claims the benefit of Japanese Patent Application No. 2010-031310 filed Feb. 16, 2010 and Japanese Patent Application No. 2011-022034 filed Feb. 3, 2011, which are hereby incorporated by reference herein in their entirety.

### INDUSTRIAL APPLICABILITY

A first Al alloy film (Al-group X element-rare-earth element alloy) according to the present invention is composed of predetermined alloy elements and a first precipitate. Thus, the first Al alloy film has excellent heat resistance when exposed to a high temperature of about 450° C. to about 600° C., and has satisfactory resistance to alkaline corrosion and low electrical resistance (wiring resistance after high-temperature treatment. Preferably, a second Al alloy film (Al-group X element-rare-earth element-Ni/Co—Cu/Ge alloy) according to the present invention is composed of predetermined alloy elements, the first precipitate, and the second precipitate. Thus, high stripping solution resistance under the high temperature described above and low contact resistance with a transparent conductive film can be provided in addition to the foregoing properties. It is therefore possible to directly connect the Al alloy film to the transparent conductive film.

According to the present invention, in particular, in a process for producing a thin-film transistor substrate including semiconductor layers composed of polycrystalline silicon and continuous grain silicon, when the substrate is exposed to a harsh high-temperature environment in which high-temperature heat treatment at about 450° C. to about 600° C. is performed and even when the high-temperature heat treatment is performed at least twice, carrier mobilities in the semiconductor silicon layers are increased, thereby improving the response speed of a TFT. It is thus possible to provide a high-performance display device that can achieve power savings and support high-speed moving images.

### REFERENCE SIGNS LIST

1a glass substrate
5 transparent electrode
25 scan line
26 gate electrode
27 gate insulating film
28 source electrode
29 drain electrode
30 semiconductor silicon layer
31 passivation film
32 low-resistance silicon layer
33 insulating passivation film

1. An Al alloy film, comprising:
at least one element X selected from the group consisting of Ta, Nb, Re, Zr, W, Mo, V, Hf, Ti, Cr, and Pt; and
a rare-earth element,
wherein
when the Al alloy film is heat treated at 450° C. to 600° C., at least one first precipitate having an equivalent circle diameter of 20 nm or more is present at a density of 500,000 particles/mm² or more, said first precipitate comprising Al, a rare-earth element, and at least one element selected from the group consisting of Ta, Nb, Re, Zr, W, Mo, V, Hf, Ti, Cr and Pt.

2. The Al alloy film of claim 1, further comprising at least one of Cu and Ge, wherein when the Al alloy film is heat treated at 450° C. to 600° C., at least one second precipitate having an equivalent circle diameter of 200 nm or more is present at a density of 10,000 particles/mm² or more, said second precipitate comprising Al, a rare-earth element, and at least one of Cu and Ge.

3. The Al alloy film of claim 2, further comprising at least one of Ni and Co, wherein when the Al alloy film is heat treated at 450° C. to 600° C., at least one third precipitate having an equivalent circle diameter of 200 nm or more is present at a density of 2,000 particles/mm² or more, said third precipitate comprising Al, a rare-earth element, and at least one of Cu and Ge.

4. The Al alloy film of claim 1, wherein the at least one first precipitate has an equivalent circle diameter of 1 μm or less.

5. The Al alloy film of claim 2, wherein the at least one second precipitate has an equivalent circle diameter of 1 μm or less.

6. The Al alloy film of claim 2, wherein the at least one third precipitate has an equivalent circle diameter of 3 μm or less.

7. The Al alloy film of claim 3, wherein the at least one third precipitate has an equivalent circle diameter of 3 μm or less.

8. The Al alloy film of claim 1, wherein a proportion of the element X is in a range of 0.1 to 5 atomic percent.

9. The Al alloy film of claim 1, wherein a the proportion of the rare-earth element in the film is in a range of 0.1 to 4 atomic percent.

10. The Al alloy film of claim 2, wherein a proportion of the at least one of Cu and Ge is in a range of 0.1 to 2 atomic percent.

11. The Al alloy film of claim 3, wherein a proportion of the at least one of Ni and Co is in a range of 0.1 to 3 atomic percent.

12. The Al alloy film of claim 1, wherein a temperature of the heat treatment is 500° C. to 600° C.

13. The Al alloy film of claim 2, wherein a temperature of the heat treatment is 500° C. to 600° C.

14. The Al alloy film of claim 3, wherein a temperature of the heat treatment is 500° C. to 600° C.

15. The Al alloy film of claim 1, wherein the Al alloy film is heat treated at least twice at 450° C. to 600° C.

16. The Al alloy film of claim 2, wherein the Al alloy film is heat treated at least twice at 450° C. to 600° C.

17. The Al alloy film of claim 3, wherein the Al alloy film is heat treated at least twice at 450° C. to 600° C.

18. The Al alloy film of claim 2, wherein the Al alloy film is directly connected to a transparent conductive film.

19. The Al alloy film of claim 3, wherein the Al alloy film is directly connected to a transparent conductive film.

20. The Al alloy film of claim 1, wherein the Al alloy film is connected to a transparent conductive film with a film comprising at least one element selected from the group consisting of Mo, Ti, W, and Cr.

21. The Al alloy film of claim 2, wherein the Al alloy film is connected to a transparent conductive film with a film comprising at least one element selected from the group consisting of Mo, Ti, W, and Cr.

22. The Al alloy film of claim 3, wherein the Al alloy film is connected to a transparent conductive film with a film comprising at least one element selected from the group consisting of Mo, Ti, W, and Cr.

23. A sputtering target, comprising:
0.1 to 5 atomic percent of at least one element X selected from the group consisting of Ta, Nb, Re, Zr, W, Mo, V, Hf, Ti, Cr, and Pt;
0.1 to 4 atomic percent of a rare-earth element; Al; and
incidental impurities.

24. The sputtering target of claim 23, further comprising 0.1 to 2 atomic percent of at least one of Cu and Ge.

25. The sputtering target of claim 24, further comprising 0.1 to 3 atomic percent of at least one of Ni and Co.

26. A display device, comprising the Al alloy film of claim 1.

27. A liquid crystal display, comprising the Al alloy film claim 1.

28. An organic electroluminescent (EL) display, comprising the Al alloy film of claim 1.

29. A field emission display, comprising the Al alloy film of claim 1.

30. A vacuum fluorescent display, comprising the Al alloy film of claim 1.

31. A plasma display, comprising the Al alloy film of claim 1.

32. An inorganic electroluminescent (EL) display, comprising the Al alloy film of claim 1.
